(19) United States
(12) Patent Application Publication
(10) Pub. No.: US 2022/0276197 A1
(43) Pub. Date: Sep. 1, 2022

(54) Floating Gate MOS Based Olfactory Sensor System

(71) Applicant: University of Manitoba, Winnipeg (CA)

(72) Inventors: Douglas A. Buchanan, Winnipeg (CA); Michael S. Freund, Halifax (CA); Vaibhav Dubey, Winnipeg (CA)

(21) Appl. No.: 17/618,760

(22) PCT Filed: Jun. 11, 2020
(86) PCT No.: PCT/CA2020/050799

§ 371 Date: Dec. 13, 2021

Related U.S. Application Data
(60) Provisional application No. 62/862,408, filed on Jun. 17, 2019.

(51) Int. Cl. G01N 27/414; H01L 29/788

(52) U.S. Cl. CPC G01N 27/4143; H01L 29/788

(57) ABSTRACT

Disclosed is an olfaction system based on integration of gas sensitive conducting polymers and Floating Gate Metal Oxide Semiconductor (FGMOS) sensors. A sensing polymer, polypyrrole for example, is electrochemically deposited onto sensor pads which are electrically connected to floating gate of the sensor. The response of these sensing polymers to any vapour analyte can be tailored using several techniques that include the use of different dopants, changing electrolyte concentrations or varying growth potential at the time of electrodeposition. Using an array of floating gate sensors, coupled to these chemically diverse polymers, this system will facilitate a signature-like response from the sensors in the array. Every sensor can be accessed and analysed individually using a specially designed addressing circuit. The response from the sensors is amplified through a trans-impedance amplifier and converted to 8-bit digital data for ease of analyte identification and quantification.

### FIELD OF THE INVENTION

The present invention relates generally to sensors, and more particularly to olfactory sensors using gas-sensitive polymers materials to detect analytes.

### BACKGROUND

Sensors are an important part of the present day electronic systems. Availability of wide variety of sensors to detect different physical responses is assisting in the design of better solutions to improve the living environment. These sensors are an essential part of many handheld devices, earning them a tag of being ‘smart’. Humans have five basic senses: vision, hearing, touch, taste and olfaction. The first three of these senses are responsive to physical interaction whereas the taste and olfaction abilities are based on chemical responses to different analytes. To develop an artificial intelligence system, capable of replicating human olfaction abilities, sensors capable of detecting chemical stimulants need to be developed.

The sense of smell provides very useful information to mammals by helping to analyse, distinguish or identify numerous odorants. Research on developing the means to extract information from odorants has grown tremendously[1][2]. The approach towards development of artificial olfactory systems generally resembles their biological counterparts where the olfactory receptors react to chemical stimuli of the odorant and generate signals for the information to be perceived by the brain. The broad and diverse range of smells mammals can process are a result of at the very least, thousands of years of evolution. Research in chemistry has shown promise and potential to develop advanced vapour sensitive materials, taking these devices closer to a truly artificial olfactory sensor platform that closely mimics its biological equivalent. The recent advancements in chemistry has given new potential materials and multiple chemical derivatives thereof, with the potential to deliver an effective olfactory sensing platform. One such class of materials is conducting polymers (CP) which exhibit a change in their electrical properties with exposure to different odorant vapours[3][4][5]. The objective of this research is to integrate these gas sensitive conducting polymers with an electronic platform for development of a small and inexpensive olfactory sensor chip.

Over the years, a number of gas sensing systems have been developed using many different sensing mechanisms[2][6][7]. The first reported olfaction system was introduced as a Mechanical nose by Moncrieff in early 19605[8]. This research was followed by development of a number of different sensing mechanisms which can be broadly categorised as metal oxide sensors, conducting polymers, bioelectronics noses, optical and/or piezoelectric sensors [2][6][7]. Most commercially available electronic nose systems are based on metal oxide sensors technology[7][9]. The metal oxide sensors have a strong sensitivity, a relatively fast response time for analyte detection and are compatible with standard silicon processing which makes them cost effective [7][9]. The operation of metal oxide gas sensors is based on principle of a change in conductance of an oxide layer when it is exposed to a gas analyte. This change in conductance is (normally) proportional to concentration of the exposed analyte[6]. The selectivity of these sensors are typically modified by doping the oxide layer with different noble metals[9]. The metal oxide sensors require high operating temperatures which is a major limiting factor. For an integrated design application, they would require an on-chip microheater which is linked to higher power consumption, making it difficult to be used in handheld or mobile devices[6][9]. However, the metal oxide sensor technology still remains the most common olfactory sensor platform and different research efforts have been reported that show an improvement in their performance. The recent work in the in implementation of such systems, use nanostructured materials such as nanowires/nanotubes as well as other new materials some of which show promise for the future of metal oxide sensor technology[10].

A bio-electronic nose is a relatively new but promising class of olfaction system based on the use of biological olfactory receptors as sensing elements for detecting different odorant molecules[2][11]. The biological sensing elements in these system are either olfactory receptor proteins or olfactory receptor cells[12]. The sensing mechanism of a bio-electronic nose is a two layer structure where the primary layer of biological olfactory receptor cells or receptor proteins, interacts with the exposed analyte vapour to generate a biochemical signal and the second layer of transducer converts it to an electrical signal[2]. Different mechanisms, such as the use of microelectrodes, resonance detection, piezoelectric layers and optical detectors have already been used as a secondary layer electrical transducer[2][12]. The bio-electronic nose has a compatibility with traditional silicon systems, which makes them economical for fabrication on a mass production scale[2][13]. The selectivity of the bioelectronic nose is high as its receptor layer is developed using biological olfactory receptor proteins/cells which are able to detect most of the odors to which a human nose can respond [14]. The sensitivity of these systems is dependent on the properties of transducer layer and its integration with biological receptor cells[14]. Recent advancements in biotechnology are helping researchers find new methods of binding the olfactory bio-cells of the bio-electronic noses to the transducer layer. New nanomaterials, like graphene and carbon nanotubes, have also been reported for their possible application in bioelectronic nose system for improving its sensitivity[2][14]. The bioelectronic nose has shown potential to be a promising olfactory sensor platform. However, there are still some limitations that include stability, repeatability of measurements and the ease of integration as a single chip olfactory sensor platform [2]. With continued research in this area, improvements in performance of bioelectronic noses can be expected in the future.

Piezoelectric sensors are very popular for wide range of sensing applications. They are also reported to be used as acoustic wave sensors in different gas sensing applications[6][7][15]. These sensors employ different piezoelectric materials to generate an acoustic wave which travels through or along their surface[15]. The nature travel for acoustic wave is used to classified sensors as surface acoustic wave sensors (SAW) or bulk acoustic wave sensor (BAW) also known as Quartz crystal microbalance (QCM) [7][15][16]. When used in gas sensing applications, these acoustic wave sensors use a thin coating of different gas sensitive materials on piezoelectric structures. Upon exposure to a vapour analyte, the gas sensitive layer interacts with vapour molecules of the analyte to produce a change in its physical properties which is reflected as a resultant change in resonant frequency of the sensor[6][15]. These sensors are designed in a silicon compatible environment which gives them advantages of small size, low power operation and lower cost because of mass production facilities. For olfactory applications, they are reported to have advantages of high sensitivity and low response time. Reproducibility of results and higher dependency on environment variables like temperature or humidity are primary causes of concern for these systems[6][7][15].

There are olfactory systems based on optical sensors for vapour detection which work on interaction of gas molecules with electromagnetic light waves. Optical sensors for olfactory systems offer multiple possibilities for extraction of information, like measurement of reflection, refraction, luminance, fluorescence, wavelength or absorbance[7][17]. This can be very helpful in designing a higher sensitivity system with a lesser number of sensors in an array. A general design of optical olfactory sensor array is incorporated with a group of multimode optical fibers with their tip coated with different gas sensitive materials, generally polymers[7][18]. The optical olfactory systems have fast response time and good sensitivity for many analytes but are complex and expensive. Packaging of these systems is an important limiting factor that needs to be addressed well in order to overcome the noise generated because of optical interference[18].

Conducting polymers, after their evolution in late 1970's, became a well-researched class of materials in the field of olfactory sensors[19][20]. Since the year 2000, when the joint Nobel Prize in chemistry was awarded to Heeger, MacDiarmid and Shirakawa “for the discovery and development of conductive polymers”, the research in this domain has intensified[20]. The conducting polymers operate at room temperature and can be easily deposited using electrochemical deposition techniques. The electrochemical process using three-electrode setup for electrodeposition of conducting polymers provides better control over the polymerization process and is a preferred method for polymer synthesis for different sensor applications [19]. The conducting polymers offer fast response time and high sensitivity towards number of analytes[20]. The sensitivity of polymers is based on a number of possible mechanisms such as oxidation or reduction of polymer, mobility variation of charge carriers in polymer chains, change in energy band structure of polymer or possible physical change such as swelling or shrinking of polymer on interaction with analyte particles[5][21]. The high sensitivity of the conducting polymers results in their lower selectivity for different analytes[22]. Techniques to improve selectivity and synthesise multiple chemically diverse conducting polymers have been reported, including the use of different monomer units for polymer synthesis, co-deposition of different monomer units to create a co-polymer, polymerisation at different oxidation potentials and the use of different dopants for polymer depositions[4][5][23][24]. Eighty-one chemically diverse conducting polymer derivatives[24] have been reported. These polymers were used for chemical identification of twelve different analytes by analysing the change in their resistivity upon exposure to these analyte vapours and then using principal component analysis techniques for processing the measurement results[24]. These findings indicate a modification in electrical properties of the conducting polymer on exposure to different analytes.

In past work, a floating gate metal oxide semiconductor (FGMOS) transistor with Polypyrrole (PPy) as the sensing polymer was successfully tested for sensitivity to different analytes[25][26]. The FGMOS is a dual gate transistor (control gate and floating gate) in which a change in the charge density on floating gate causes a shift in its normal electrical characteristics.

Further research and development was undertaken by the inventive entity of the present application to build and improve upon the forgoing groundwork laid in the field of olfactory sensing technology.

### SUMMARY OF THE INVENTION

According to a first aspect of the invention, there is provided a floating gate metal oxide semiconductor (FGMOS) transistor comprising:

a substrate having a source region, a drain region, and a channel region residing therebetween;

gate stack layers deposited on said substrate, among which there is defined a stacked gate structure that resides in overlying relation to the channel region, and comprises, in sequential order starting from said substrate, a first dielectric layer, a floating gate, a second dielectric layer and a control gate;

an extension pad that resides in exposed condition outside said stacked gate structure, comprises a constituent material of an outermost conductive layer of said gate stack layers situated furthest from the substrate, and is conductively linked to the floating gate; and

a floating gate terminal by which an electrical bias is applicable to the floating gate and the extension pad conductively linked thereto for use in electrodeposition of a conducting polymer onto said extension pad.

According to a second aspect of the invention, there is provided a sensing device comprising an array of sensors each comprising a respective transistor of the forgoing type, wherein the extension pads of the transistors of at least some of the sensors comprise outer surfaces composed of polymer material of varying chemical composition to one another.

According to a third aspect of the invention, there is provided a method of producing the sensing device of the forging type recited in the second aspect of the invention, said method comprising performing electrodeposition of chemically diverse polymeric films onto the extension pads of different subsets of said sensors basis by, for each subset of said sensors, applying an electrical bias to the extension pad(s) of said subset while said subset is submerged in a polymer precursor solution in order to deposit a respective polymer film onto the extension pad(s) of said subset.

### BRIEF DESCRIPTION OF THE DRAWINGS

One embodiment of the invention will now be described in conjunction with the accompanying drawings in which:

FIG. 1 is a schematic diagram of a cross sectional view of a conventional n-type FGMOS transistor.

FIG. 2 is an Energy Band diagram of an n-type FGMOS demonstrating Fowler Nordheim tunneling from the substrate to the floating gate.

FIG. 3 schematically illustrates an n-type FGMOS transistor of the present invention, with a floating gate extension pad (electronically connected to the floating gate of the FGMOS) positioned in an exposed condition outside of the gate stack for application of a vapor-sensitive polymer thereto to create an olfactory sensor of the present invention.

FIG. 4 is a schematic representation of a bias setup for the FGMOS sensor of FIG. 3 and shows the expected change in the sensor current upon exposure to different vapor analytes

FIG. 5 is a block schematic for an olfactory sensing device of the present invention employing an array of olfactory sensors of the type shown in FIG. 3.

FIG. 6 schematically illustrates the address and control signal circuitry of the olfactory sensing device of FIG. 5 to address and control the sensor array thereof.

FIG. 7 schematically illustrates the individual sensor addressing in the sensor array.

FIG. 8 is a schematic diagram of a transimpedance amplifier circuit of the sensing device of FIG. 5.

FIG. 9 shows simulated electrical response of the transimpedance amplifier of FIG. 8.

FIG. 10 is a schematic block diagram of an analog to digital converter of the sensing device of FIG. 5.

FIG. 11 shows (a) nickel coated floating gate extension pads of the sensor array; (b) an SEM image of those nickel coated surfaces; and (c) EDS (Energy-Dispersive X-ray Spectroscopy) analysis for the surfaces to confirm presence of the nickel layer.

FIG. 12 shows (a) gold coated floating gate extension pads of the sensor array; (b) an SEM image of those gold coated surfaces; and (c) EDS analysis for the surfaces to confirm presence of the gold layer.

FIG. 13 shows a packaged chip embodying the sensing device, and featuring selective encapsulation of wirebonds using SU-8 photoresist.

FIG. 14 shows cycling behavior of 0.1 M Pyrrole, 0.1 M H₂SO₄ solution in deionized water, with pointers on the trace that highlight favourable redox potentials for growth of conducting polymers onto the floating gate extension pads of the sensor array.

FIG. 15 shows chemically diverse conducting polymer films grown on the floating gate extension pads of the sensor array in a prototype of the sensing device.

FIG. 16 schematically illustrates a gas flow setup for characterization of the sensing device in a controlled analyte vapour environment.

FIG. 17 illustrates the electrical characteristics of a tested FGMOS sensor of the present invention.

FIG. 18 shows (a) change in measured source-drain current after exposure of the tested FGMOS sensor to 100% methanol environment; and illustrates (b) how nitrogen flow helps the sensor regain its original electrical properties.

FIG. 19 shows source-drain current measurements for a Polypyrrole coated sensor for 4 different analytes, compared to an initial source-drain current in Nitrogen.

FIG. 20 shows transfer characteristics of a Polypyrrole coated sensor, and includes a rescaled plot of such characteristics on a linear scale of source-drain current.

FIG. 21 shows on-chip circuitry of the sensing device connected to an interdigitated electrode (IDE) coated with Polypyrrole film for testing purposes.

FIG. 22 shows response of the test setup of FIG. 21 in 20% analyte environment.

FIG. 23 shows Transimpedance Amplifier output voltage comparison of the test setup of FIG. 21 in 30% Methanol vapours using two chemically different PPy films deposited on respective IDEs at 0.7V and 1.2V.

FIG. 24 shows addition of a high gain differential mode amplifier between the transimpedance amplifier of the test setup of FIG. 21 and an A/D converter.

FIG. 25 shows the response of the test setup of FIG. 24 in terms of amplifier voltage for 30% flow of six different vapour analytes using Polypyrrole as the sensing polymer.

FIG. 26 shows (a) transfer characteristics of a PPy/pTSA coated on-chip sensor in 6 different analytes and (b) a rescaled plot of it on linear scale of drain current.

FIG. 27 shows (a) transfer characteristics of a PPy/Oxalic acid coated sensor in 6 different analytes and (b) a rescaled plot of it on linear scale of drain current.

FIG. 28 shows (a) transfer characteristics of a PPy/KCl coated sensor in 6 different analytes and (b) a rescaled plot of it on linear scale of drain current.

FIG. 29 shows (a) transfer characteristics of a PPy/pTSA coated sensor in 6 different analytes and (b) a rescaled plot of it on linear scale of drain current.

FIG. 30 shows (a) transfer characteristics of a PANI/H₂SO₄ coated sensor in 6 different analytes and (b) a rescaled plot of it on linear scale of drain current.

FIG. 31 shows (a) transfer characteristics of a PANI/pTSA coated sensor in 6 different analytes and (b) a rescaled plot of it on linear scale of drain current.

FIG. 32 shows a normalised threshold voltage (ΔV_{THN}) relative to nitrogen for 4 PPy and 2 PANI based sensors doped with variable dopants for their exposure to 6 analytes.

FIG. 33 shows a normalised change in sensor current of 4 PPy and 2 PANI based sensors doped with variable dopants for their exposure to 6 analytes.

FIG. 34 shows transient response of a PPy/pTSA based sensor for exposure to 4 analytes.

FIG. 35 shows transient response of a PPy/H₂SO₄ based sensor for cyclic exposure to nitrogen and toluene.

FIG. 36 shows transient response of a PPy/H₂SO₄ based sensor for exposure to methanol.

FIG. 37 shows transient response of a PPy/H₂SO₄ based sensor for exposure to 4 analytes.

FIG. 38 shows transient response of a PPy/KCl based sensor for exposure to different concentration of petrol vapours.

FIG. 39 shows transient response of a PPy/Oxalic acid based sensor for exposure to different concentration of water vapours.

FIG. 40 shows transient response of a PANI/pTSA based sensor for exposure to water and petrol.

FIG. 41 shows transient response of a PANI/pTSA based sensor for exposure to different concentrations of water vapour.

FIG. 42 shows transient response of a PANI/pTSA based sensor for exposure to different concentrations of methanol.

FIG. 43 shows transient response of a PAN I/H₂SO₄ based sensor for exposure to water vapour.

### DETAILED DESCRIPTION

One objective of the research behind the present invention was to develop a small, inexpensive programmable olfactory sensor platform using a commercially available silicon technology. The Complementary Metal Oxide Semiconductor (CMOS) devices on the silicon substrate are used as the fundamental building blocks for many integrated circuits in present day electronics. The CMOS technology has many advantages that include high speed of operation, low power consumption and a well-established mass production technology.

The Floating Gate Metal Oxide Semiconductor (FGMOS) transistor is well-known device that had been used extensively in flash semiconductor memories. It also has been used as a sensor in many electronic systems[27][28]. The structure of FGMOS transistor is different from that of conventional CMOS transistors in terms of number of gate terminals. The FGMOS transistor has two gate terminals, referred as the control gate and the floating gate. These transistor gate structures are designed with polysilicon layers and a silicon technology with two distinct polysilicon layers is required. In building and testing prototypes of the present invention, a 0.35 μm silicon technology available through Taiwan Semiconductor Manufacturing Company (TSMC) was used for the fabrication of the integrated circuit design. This 0.35 μm silicon technology is one of the few available that offer two polysilicon layers.

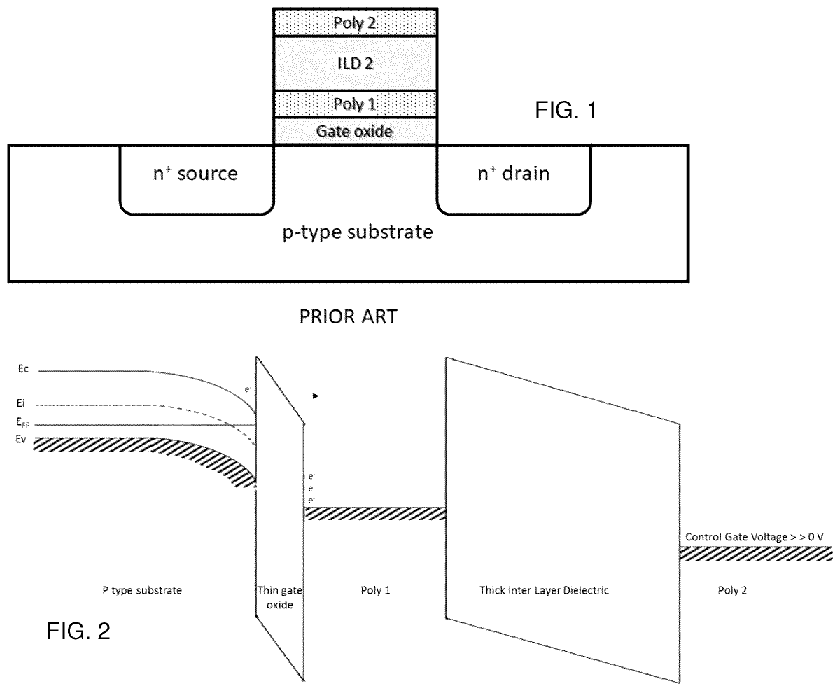

In FIG. 1 a schematic view of an n-type FGMOS transistor is shown. The lower polysilicon layer (poly1) is the “floating gate” and is isolated from the silicon substrate by a thin insulating layer of silicon dioxide. The upper polysilicon layer (poly2) forms the control gate, which overlaps the floating gate (poly1) as is sandwiched between a thick layer of dielectric (ILD2) and the thin gate oxide. These gate terminals in the FGMOS structure are capacitively coupled to each other. In normal mode of operation of an FGMOS structure, charge carriers from substrate are tunneled through the thin layer of gate oxide onto the floating gate layer of the device by applying a suitable electrical bias condition. As the floating gate structure is electrically isolated from the substrate as well as the control gate, the charge on floating gate gets trapped. The trapped charge on floating gate layer modifies the electrical characteristics (specifically, although not exclusively, the threshold voltage, VTH) of the FGMOS structure with respect to its operation from control gate[29]. The magnitude of the change in the device characteristics is dependent on density of trapped charge on to the floating gate layer[26]. The trapped charge can also be removed from floating gate using the reverse electric gate potential which in turn returns the device to its original electrical characteristics. This mechanism is the principle of write/erase operation in flash semiconductor memories.

There are different tunnelling mechanisms responsible for the charge transfer in the FGMOS devices. The most common mechanism is based on Fowler Nordheim (FN) tunneling[30]. The energy band diagram of the FGMOS if shown in FIG. 2.2 demonstrates the gate oxide tunneling effect when large control gate voltages are applied[31]. The Fowler Nordheim tunneling mechanism is a field dependent tunneling phenomenon that can occur when a large electric field is generated across gate oxide when a very high gate voltage is applied. When the control gate terminal of poly2 layer is kept at a positive potential with respect to substrate potential, the generated electric field excites an accumulation of minority charge carriers (electrons) from the substrate close to the oxide substrate interface. For very high electric fields, some of these electrons from conduction band of the substrate may acquire enough energy to tunnel through the triangular portion of the top of the potential barrier of thin gate oxide layer. The thick inter layer dielectric (ILD2) represents a large potential barrier for these electrons to travel through to the control gate and as such the tunnelled electrons become trapped onto the floating gate layer of poly1. The trapped charge of floating gate also produces an image charge at the oxide interface which results in effective lowering of barrier height[32]. Due to this trapped charge, a shift in the normal FGMOS electrical characteristics is observed. The process of removal of charge also results from FN tunneling mechanism where a large reverse gate potential excites trapped electrons to escape through the thin oxide barrier back to the substrate.

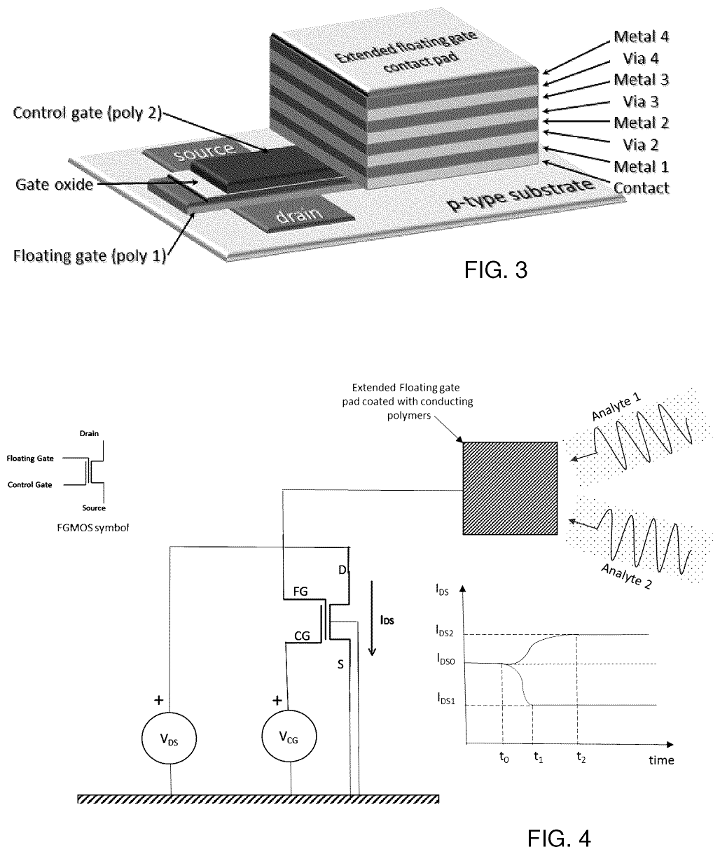

A 3D representation of a novel FGMOS sensor structure of the present invention is shown in FIG. 3. In the illustrated embodiment, a modification in the basic structure of the FGMOS transistor is employed to allow easy accessibility to floating gate terminal[25]. Usually the floating gate of poly1 layer is buried under multiple layers, namely the ILD2 layer, the control gate poly2 layer and all of the four metal and inter-dielectric layers. To create an electrical connection to the poly1 layer within a conventional FGMOS transistor layout, a series of complicated and difficult selective etching steps would be required on the already fabricated chips. To avoid these difficult post processing steps, the novel FGMOS structure was designed with an electrical extension of the floating gate layer connected to the uppermost conductive layer of the transistor's topology, specifically the fourth and topmost metal layer (M4) in the instance of this 0.35 μm silicon implementation.

This top metal layer (M4) from this 0.35 μm silicon technology is thus used as an extension pad that is conductively connected to the floating gate poly1 layer of the sensor. To create the floating gate layer connectivity to the topmost metal layer, a stacked bridging structure is created that connects all of the intermediate metal and via layers between the poly1 layer and the top metal layer (M4). For example, the first metal layer (M1) is connected to the floating gate poly1 layer using a “CONTACT” hole though the first inter-layer-dielectric (ILD1) sandwiched between poly1 and M1. The second metal layer (M2) is then connected to M1 through a first via “VIA1” in the second inter-layer-dielectric ILD2 layer sandwiched between M1 and M2, and so on through to M4. The different stacked structures formed among the overall topology of gate stack layers of the FGMOS transistor can be seen in FIG. 3. The stacked gate structure can be seen to the left of the FGMOS and is composed of, in sequential order starting from the silicon substrate, a first dielectric layer, a floating gate (poly1), a second dielectric layer and a control gate (poly1). At the right side of the figure, the floating gate extension pad is seen to reside outside the stacked gate structure. The bridging structure has its alternating dielectric and metal layers stacked atop the floating gate at an area thereof exposed outwardly from under the control gate layer. These alternating layers of the bridging structure span the height of the thick dielectric layer underneath the extension pad. The contact hole and vias in each of the dielectric layers of the bridging structure conductively link the metal layers M1 through M4 thereof, thereby connecting the M4 extension pad to the floating gate (poly1).

The floating gate extension pad is the surface onto which the conducting polymers are electrochemically deposited, effectively functionalizing the active sensing area of the sensor. Unfortunately, all four metal layers in this 0.35 μm silicon technology are made from aluminum, which oxidizes and inhibits the electrodeposition of the polymers. To overcome this problem, in preferred embodiments of the present invention, a layer of gold is selectively electrodeposited onto the floating gate extension pad using several post processing steps. In a clean room environment, a process for the selective electroless deposition of gold onto the aluminium extensions was developed, as described in more detail below. The now gold-coated surface of the floating gate extension pad is used as the working electrode of the sensor for the electrodeposition of the desired conducting polymer to be used for olfactory sensing functionality. After successfully depositing the polymer onto the extension pad, characterization of the sensor systems is conducted in a controlled electrical and analyte environment.

The operation of the FGMOS sensor is dependent upon the applied electrical bias to the gates, source, drain and substrate terminals, as well as any charge that has been induced on the floating gate when the conducting polymer on the extension pad interacts with an analyte vapor. In FIG. 4 a schematic of the typical electrical bias setup used for testing the FGMOS sensor is shown. A scenario representing an interaction of different analytes with the conducting polymer causing change in sensor current is also shown. The FGMOS sensor is biased with a positive (with respect to the source and substrate) DC bias applied to the drain and control gate terminals, V_{DS} and V_{CG}, respectively. Under these bias conditions a constant source-drain current of Ipso flows through the sensor as shown schematically in FIG. 4.

Each conducting polymer responds in a unique way to different vapour analytes. An example of the time dependence of the source-drain current (I_{DS}) is shown in FIG. 4, which demonstrates the change in the sensor current (ID₅₀) when an analyte vapour interacts with the polymer film. Depending on the type of interaction, the variation in source-drain current can be positive or negative, as demonstrated in FIG. 4 for two different scenarios, where the initial source-drain current of ID₅₀ decreased to I_{DS1} or increased to I_{DS2}. Different chemical mechanisms, like oxidation or reduction reactions, upon interaction of vapour analyte with polymer molecules may result in generation of charge in polymer layer. The generated charge will result in change in source-drain current from its initial value. The response time for source-drain current transition will be dependent on the sensitivity of an individual polymer reaction to a specific vapour analyte.

The basic feasibility of this type of sensor functionality, though without the novel extension pad of the present invention, has been previously verified [25]. However, to provide a chemically diverse olfactory sensor system, embodiments of the present invention include a novel chip having an array of FGMOS sensors thereon, along with associated electronic control circuits need, all integrated onto a single silicon substrate.

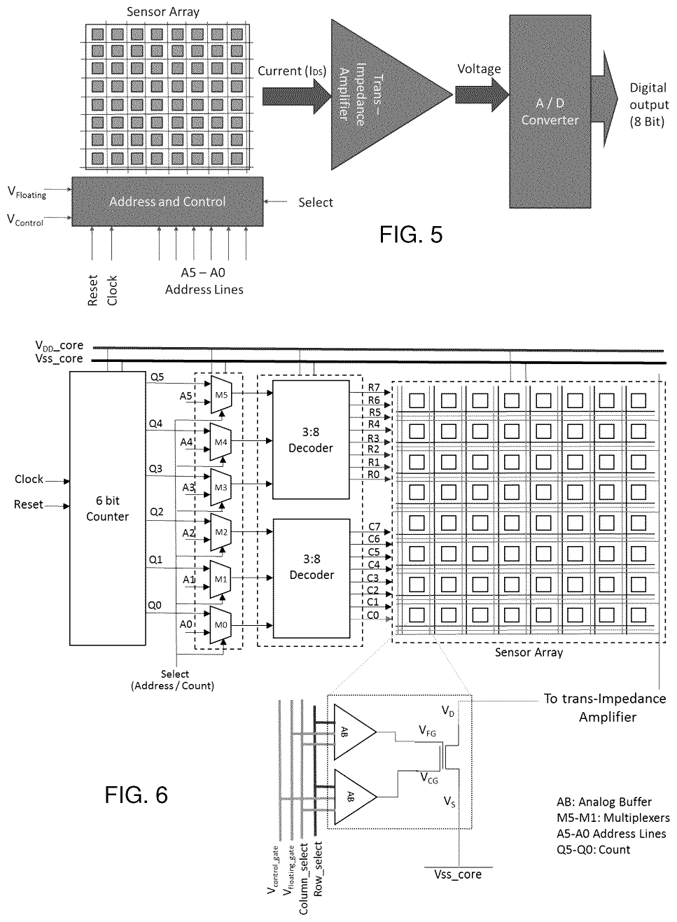

A schematic view of such an embodiment is shown in FIG. 5. Prototypes of such chips have been fabricated, and each contain an 8×8 array of sensors, of which each individual sensor is accessible using, for example, a specially designed addressing circuit. The change in electrical response of this sensor, upon interaction with different vapour analytes can be very small and range from a few picoamperes to 10's of microamperes, some 6-7 orders of magnitude. To accommodate this large “exponential” change in current, a novel logarithmic transimpedance amplifier was designed, the linear voltage output of which is to be then converted to a digital signal using an analog to digital converter (A/D) to produce a digital output. The functional verification of the addressing, amplifying and conversion circuits has been performed, and used to develop an optimized version of the system. In the illustrated embodiment, this was an 8-bit digital signal in the interest of simplicity and speed, though the bit size may be increased notably to achieve greater accuracy.

The sensors in the array require suitable electrical signals to bias them in a favourable operating region. Access to each extended floating gate sensor pad individually is required for the selective electrodeposition of the polymers. To provide an automated addressing scheme for system testing, a special address and control circuit was designed using counters, multiplexers, decoders and analog buffers as shown in FIG. 6.

All the circuit schematics were designed in Cadence Virtuoso schematic composer using TSMC 0.35 μm technology parameters. The address and control circuit of the illustrated embodiment has two operational modes. In a manual mode, the sensors in the array can be addressed manually using the address lines A5-A0 to generate a 6-bit address for all 64 sensors. In the automated mode of address generation, a clock signal is used to trigger a 6-bit counter circuit which counts through all addresses automatically. An array of six multiplexer circuits is used to switch in-between these two modes. The 6-bit address generated by counter or address lines is used to control 8 rows and 8 columns buses that run through the array of sensors. The signals for these row and column buses are generated by decoding the 3-bit address signal to 8-bits using two 3:8 decoder circuits. Every row and column bus combination is used to excite an individual array cell which has one FGMOS sensor of the type disclosed above with the novel polymer coated extension pad, a set of digital gates and two specially designed analog buffer circuits. The digital AND gate uses inputs from row and column bus to generate an output which is used to enable our buffer circuits. An ON-state buffer connects the gate terminals of FGMOS sensor to external pins which are used to pass electrical signals to the sensor. In the manually-addressed programming or setup mode, these electrical signals are used for the polymer electrodeposition onto the extension pads of the arrayed sensors to create the finished sensing device ready for use. In automatically-addressed sensing mode of the finished device, electrical signals are used to perform the analyte detection process.

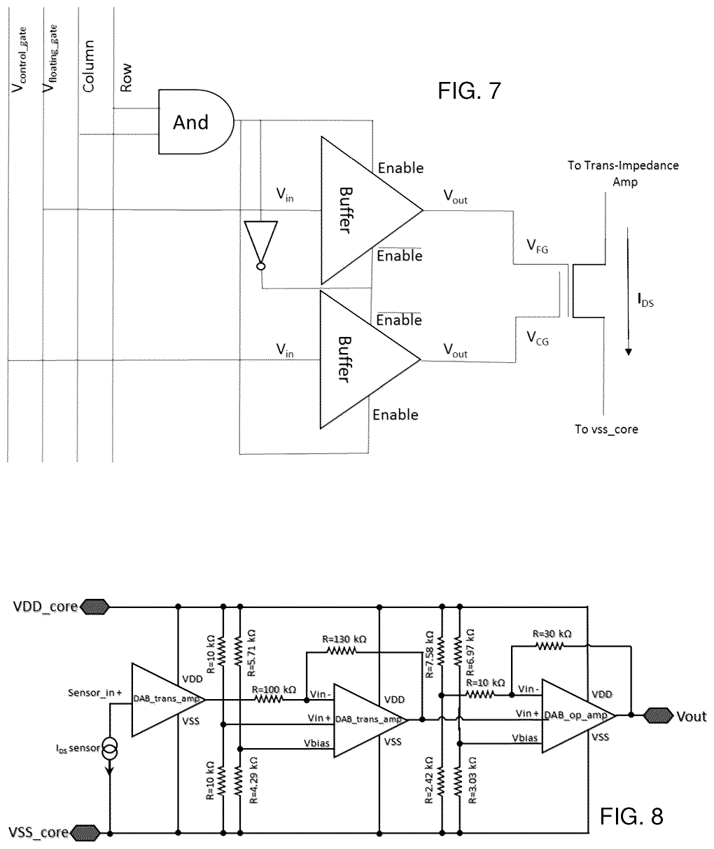

Two analog buffer circuits are used in each array cell to transmit the floating gate and control gate voltages from respective floating gate and control gate signal lines V_{control_gate} and V_{floating_gate} to the floating gate and the control gate terminals, respectively, of the FGMOS sensor of the cell as shown in FIG. 7. An output enablement terminal of the respective buffer that feeds each gate terminal is connected to the AND gate fed by the row and column busses, whereby the control voltage from either signal line is only passed on to the respective gate terminal when the row and column address of the given sensor of the array is transmitted over the row and column busses, whether in a manually specified basis in the programming or setup mode, or in an automated fashion in the sensing mode. The floating gate terminal is normally left floating and is biased only during the electrodeposition of the polymers. That is, the floating gate signal line is only ever energized in the programming or setup mode, and not in the sensing mode of the finished sensing device. On the other hand, in the sensing mode, the source-drain current of each sensor is controlled with a suitable control gate bias applied via the control gate signal line. This sensor current is fed into a transimpedance amplifier to convert the exponential change of the sensor current to a linear output voltage.

To create the greatest sensitivity, the FGMOS sensors can be biased in the subthreshold or weak inversion region of operation where a slight change in floating gate voltage produces a substantial change in sensor source-drain current. For a linear change in the control gate voltage, the source-drain current changes exponentially and its magnitude can range from a few nanoamperes to many microamperes. To rescale this exponential response onto a linear voltage scale, a transimpedance amplifier circuit may be used, such as that schematically shown in FIG. 8. The first stage for the transimpedance amplifier circuits is a logarithmic amplifier which converts the exponential input current to a linear output voltage. However, the voltage at the output of first stage is very low. Preferably, the amplifier has maximum possible output voltage swing within the supply limits, from 0-3.3 V for this 0.35 μm CMOS technology. To achieve the output voltage swing, two high gain operational amplifier stages may be employed to rescale the output voltage from first stage. The gain of these stages was designed to achieve linear output voltage swing of around 90% of the supply voltage.′

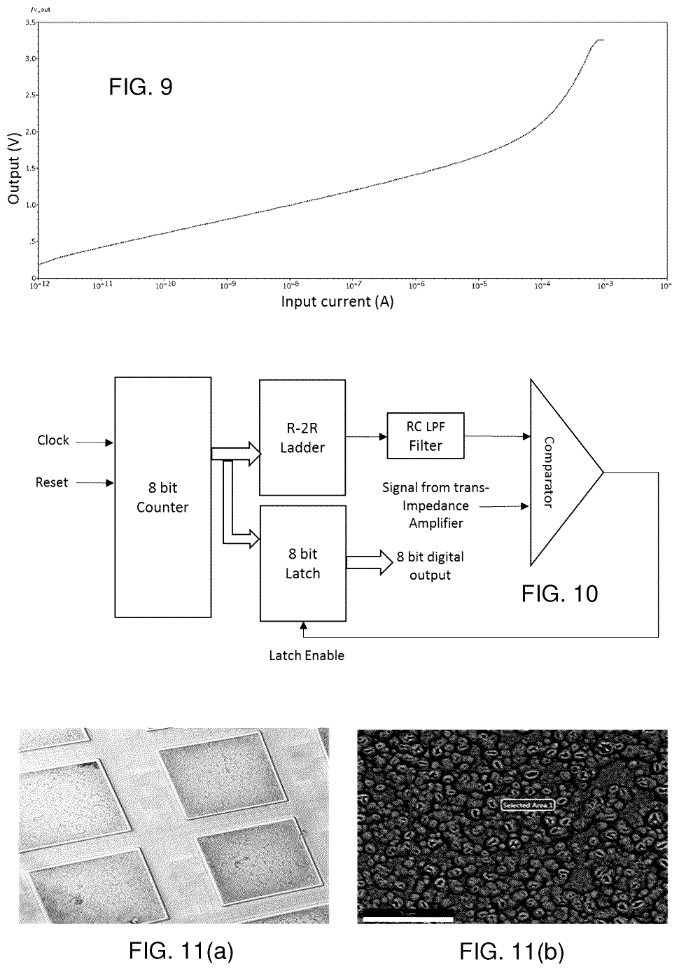

The transimpedance amplifier output voltage from a simulation is shown in FIG. 9. The simulation result shows that for input current change from 1 pA to 1 mA, the transimpedance amplifier would be able to produce a wide voltage swing from 200 mV to 3.2 V which slightly less that the voltage limits, 0-3.3 V. During some initial testing, of one of the previous designs, a loading effect of the transimpedance amplifier on the sensor current was discovered. To overcome this problem, a current mirror circuit was added in-between the sensor and transimpedance amplifier, which by removing a direct connection between the sensor and the amplifier, resulted in a more stable operation.

The final stage of this sensor array system is an analog to digital (A/D) converter designed to produce an 8-bit digital result from the amplifier output. The 8-bit A/D converter yields a voltage resolution of 13 mV (3.3 V/255) which means the sensor can discriminate (a 1-bit change) between voltages having a difference of more than 13 mV. The digital data from the entire array, given that each of the sensors could contain a different polymer, and react differently to given group of analytes, can collectively produce a “digital” fingerprint or 2D “image” for a given analyte. The digital information is easier to store and process. Therefore the A/D converter may be included on the chip in the interest of decreasing the complexities in development of processing algorithms by representing information in more convenient digital form. A block schematic for one embodiment of A/D converter implementation on the chip is shown in FIG. 10.

In the illustrated example, the 8-bit counter is synchronized to the clock which is incremented on the positive edge of the clock. The output bus of the counter is connected to an R-2R ladder circuit which converts the 8-bit binary number generated by the counter to its equivalent voltage level. For a counter counting up the R-2R circuit will generate a ramp signal of voltages for every cycle of the count. The analog ramp signal generated with R-2R circuit has high frequency components from the clock superimposed on the voltage ramp. To minimize these high frequency components and its effect on circuit operation, a low pass filter is used between the R-2R ladder circuit and the comparator. The filtered voltage ramp signal is then compared with the output voltage of trans-impedance amplifier using a comparator circuit. Once the ramp signal voltage exceeds the trans-impedance amplifier output, the comparator generates a trigger signal which is used as a latch enable control signal for an 8-bit latch circuit which stores the data. Hence an 8-bit digital number, equivalent to the voltage generated by trans-impedance amplifier output is latched at the output of the A/D converter. A number of simulations were performed to evaluate the performance of the A/D converter circuit. The simulation results show good linearity between the analog input and the digital output for our A/D converter. The primary limitation of the A/D converter is the long high response time as it could require it run through all possible 256 digital states (i.e. 256 clock cycles) to find a match with the input signal. The response time of the polymers to detect presence of any vapour analyte is usually much longer that this response time (256/clock), therefore this A/D circuit is suitable for this application.

The chips from three different fabrication runs were tested for electrical performance of the inventive sensing device employing an array of sensors, each having the novel FGMOS design with the polymer coated extension pad.

Under ideal circumstances, the integration of the polymers with the extended floating gate pad of the sensor should require only one process of electrodeposition of a given polymer. However, past experiences have shown that the polymers do not deposit well on the aluminum surface of the M4 extended floating gate pads of this 0.35 μm silicon-based implementation. In fact, it was observed that instead of polymer deposition, an etching of the aluminium layer was observed[26]. An ideal solution is to coat the surface of extended floating gate pads with some non-oxidizing, non-reactive noble metal. Gold is often used in a thin from for the deposition of organic polymers using the an electrochemical process[33]. It was believed and subsequently discovered that Au would be a suitable metal to work with these chips. However, the process of selective deposition of gold onto the contact pad surface using a standard lithography technique would be difficult to perform due to the size of this silicon chips (˜3×5 mm). Coating the contact pad surface using electroplating is promising but the conventional electroplating process would require a series of electrical connections which would be very complex. An electroless deposition technique for plating has been shown to be an easy and reproducible process with compatibility of electrodeposition on a micron scale[34]. The electroless plating process simply requires only an aqueous solution of the target material and works without the need of any external electrical connections. The aqueous solution used for electroless plating contains a reducing agent for the target material which triggers a chemical reaction when the substrate electrode is immersed into the solution, resulting in reduction of target material onto the substrate, effectively coating it.

Aluminium is very reactive to presence of oxygen and forms a thin native oxide layer on its surface soon after it comes in contact with any oxygen environment. This native oxide layer prevents direct contact with the aluminium surface which makes the electroplating of gold onto the aluminium contact pads very difficult. A well-known industrial solution to this problem includes a three-stage plating process for electroplating gold onto an aluminum surface. The process requires sequential plating of zinc, nickel and then gold layers onto a clean aluminium surface. Some researchers[34] have reported that this process is compatible with microelectronics applications.

Before the plating process is begun, it is very important to clean the surface of the chips to ensure a homogenous deposition. The chips may be rinsed thoroughly in organic solvents (methanol and acetone) followed by a deionised water rinse to remove any organic contaminants. The chips are then immersed into a room temperature aqueous solution of “zincate” a zinc compound from Casewell Inc. The zincate solution first etches the thin aluminium oxide layer present on the surface and immediately follows it up with the deposition of zinc onto the surface which prevents re-oxidation of the aluminium until the next plating process is initiated. The zincate solution is alkaline in nature and can generate complex intermetallic compounds of aluminium which are found to be insoluble in the zincate solution[35]. These insoluble compounds are known as ‘smut’ which can adversely affect the uniformity of the following electroplated layers. To achieve uniformly electroplated surfaces, a process of “desmutting” with a dilute nitric acid solution followed by one more zincate baths may be used. This combined process is called as double zincate process. Desmutting after first zinc bath helps in stripping of undesired smut and nucleated zinc depositions onto the surface of aluminium which helps achieve a homogenous, thin zinc layer on the aluminium surface[35]. The presence of zincate layer on top of aluminium surface was confirmed with optical microscope images and energy dispersive x-ray spectroscopy (EDS) using a FEI Quanta 650 scanning electron microscope available through the Manitoba Institute of Materials at University of Manitoba. The zinc coated samples were processed for electroless nickel growth using another plating solution purchased from Casewell Inc.

The nickel bath requires a proportionate mixing of three nickel concentrates to prepare the final plating solution. The electroless deposition of nickel is an autocatalytic process where the product of the initial chemical reaction acts as the catalyst for the next chemical reactions. The process may employ a bath temperature of 90° C. to trigger the autocatalytic process. When the zincated samples are immersed in the heated nickel bath, a uniform deposition of a nickel film is formed onto the zinc at the plating rate of 400 nm/minute begins.

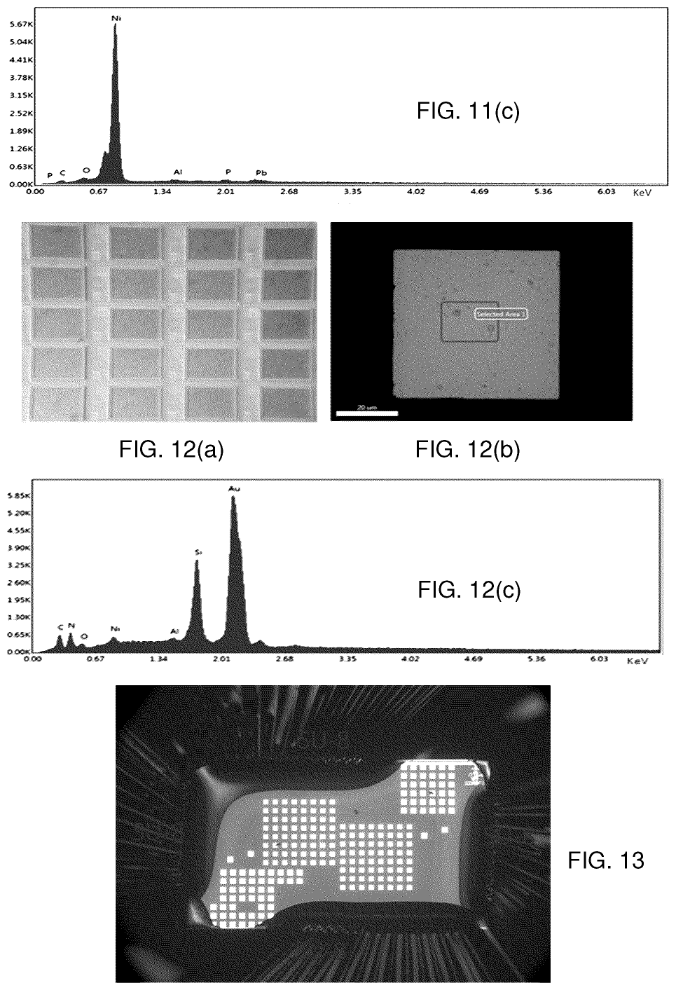

The thickness of the plated nickel layer may be controlled using the immersion time of the samples in the heated nickel bath. An immersion time of 75 seconds with constant agitation of 100 rpm may be used to achieve approximately a 500 nm thick nickel layer. To confirm the successful deposition of a uniform nickel films on the extended floating gate pad surface, optical microscope images were taken. A uniform metallic appearance of the surface as seen in FIG. 11 (a) was observed to be different from the previously deposited zincate layer. The color of aluminium surface is very similar to the observed layer which raised some concern whether the zincate surface was actually coated with nickel or etched away in nickel bath exposing underlying aluminium layer. Energy dispersive x-ray spectroscopy (EDS) was then used on a selected area of the electroplated surface as shown in the FIG. 11 (b). The element composition map (FIG. 11(c)) shows that nickel is the primary component on the surface of extended floating gate pads. The final process in the tested sequence was the electroless gold deposition as described below.

A cyanide free immersion gold solution was ordered from Transene Company Inc., Canada. The process may employ a bath temperature of 75° C. to initiate electroless gold depositions, which was found to have a typical deposition rate of −25 nm/minute. This solution was agitated at 100 rpm to ensure uniform depositions. The nickel coated samples were immersed in the heated gold bath for 2 minutes. A bright gold appearance of extended floating gate pads surface was easily visible using the microscope and was again verified using EDS analysis. The electroless plating technique gave an easy and efficient process of producing a gold coated surface for the extended floating gate pads. The next stage was the electrodeposition of the polymers onto these gold-coated surfaces. For simplicity, the initial polymer employed in the tests was limited to polypyrrole, though it will be appreciated that other polymers (conductive or otherwise), may be employed.

For the process of electrodeposition of the conducting polymers, a three-electrode electrochemical cell was used with a platinum electrode as the counter electrode, a silver-silver chloride (Ag/AgCl) electrode as the reference electrode, and the extension pad surface to be electroplated acting as the working electrode. Every electrode the potential was measured with respect to the standard potential of the Ag/AgCl reference electrode. The process of electromigration occurs in-between working and counter electrode where the working electrode acts as a site for the Oxidation-Reduction (Redox) reactions for polymer deposition. The counter electrode acts as source or sink of the charge carriers[36]. Redox potentials for polymer depositions are selected from the analysis of the cyclic voltammetry experiments where working electrode potential is ramped linearly in time while the current is measured.

The chips were packaged in CPGA 69 ceramic packages where the Au bond wires connect electrical terminals from the chip to external pins of the package. The bond wires used are very delicate (˜25 μm diameter) and require very careful handling. In the process of electrodepositing the conducting polymers, whenever electrical potential is formed on the bond wirebonds, polymer deposition can occur. This creates a very undesirable scenario resulting in polymer depositions on undesired places and can in some cases create an electrical short between terminals. To protect the wirebonds from physical forces while processing and have them electrically isolated from the electroplating solution, SU-8 photoresist was used as an insulating layer for the encapsulation of the wirebonds. The SU-8 was carefully injected onto desired wirebonds areas using a medical syringe to achieve the selective encapsulation. The SU-8 coating successfully provided the required physical support to wirebonds but also kept them electrically isolated from electrodeposition solution. A chip processed with this selective encapsulation of wirebonds is shown in FIG. 13. The encapsulated chip with the gold coated extended floating gate pads was used for the electrodeposition of conducting polymers. The chip would require suitable electrical signals for the designed address and control circuit. A Verilog code running on an FPGA board was used for the generation of the required electrical signals for address and control logic. The code was implemented on an Altera DE2-115 development board. The GPIO pins on the board were configured to pass the required electrical signals to the chip. As the signals were passed to the chip, the polymer was deposited on individual sensors in the array.

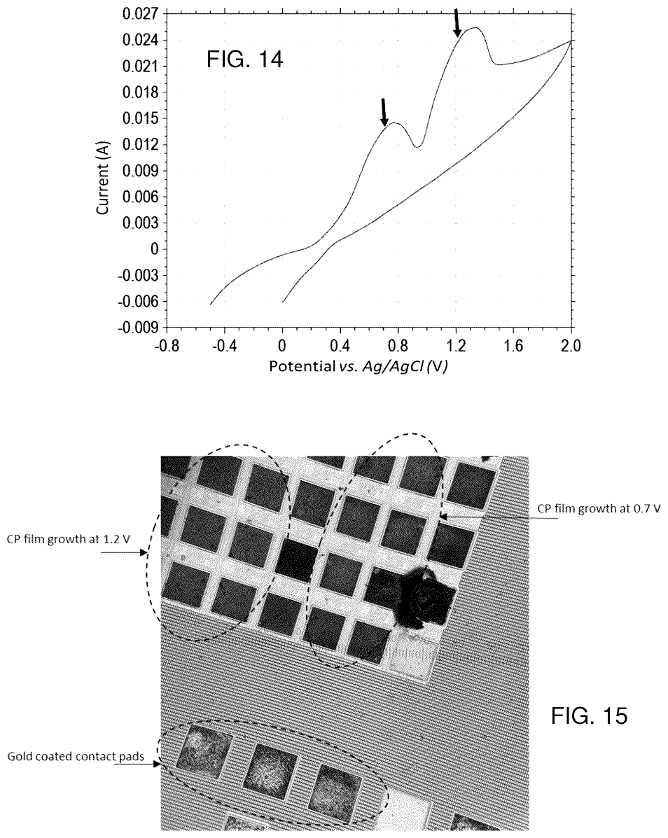

An aqueous polymer precursor solution used for the electrodeposition of polypyrrole was prepared with a 0.1 M pyrrole solution with a 0.1 M H₂SO₄ in 20 ml of deionised water. A CH Instruments® model 760C potentiostat was used to generate the required electric potentials for the three-electrode deposition setup. Cyclic voltammetry was conducted to observe the electroactivity of the pyrrole monomer in the solution and to find out the available redox potentials suitable for deposition of conducting polymer. FIG. 14 shows the cyclic voltammetry (CV) results of a 0.1M Pyrrole and a 0.1M H₂SO₄ solution in 20 ml of deionized water. The potentials highlighted with the arrows on the CV trace (0.7V and 1.2V) are favorable redox regions for the deposition of conducting polymers. These two potentials used for electrodeposition of conducting polymers were applied separately to the extended floating gate pads of the sensors. That is, the 0.7V potential was applied to the floating gate extension pads of a first subset of the sensors during immersion of the array in the polymer precursor solution during one polymeric deposition process, while the 1.2V potential was instead applied to the floating gate extension pads of a different second subset of the sensors during immersion of the array in the polymer precursor solution during another polymeric deposition process. The polymer films deposited at different growth potentials have been reported to have different chemical composition and have had observable differences in the color of the films[24]. In FIG. 15, a microscope image of an electrochemically deposited and compositionally different conducting polymer is shown after depositions onto the surface of the floating gate extension pads of different sensor subsets in the array.

Some sensors of the array were used to test the deposition rate of polymer film and to decide upon the time constraints for a uniform deposition. It was observed that 30 seconds was a suitable time for electrodeposition of a uniform thin film of polypyrrole. Using the automated address generation Verilog code, the Altera DE2-115 development board was used to address each sensor in the array and coat the extended floating gate pad of that addressed sensor at one of two different redox potentials of 0.7 V and 1.2V. The polymer films deposited at 0.7 V had a brownish appearance while the polymer films at 1.2 V were gray in color.

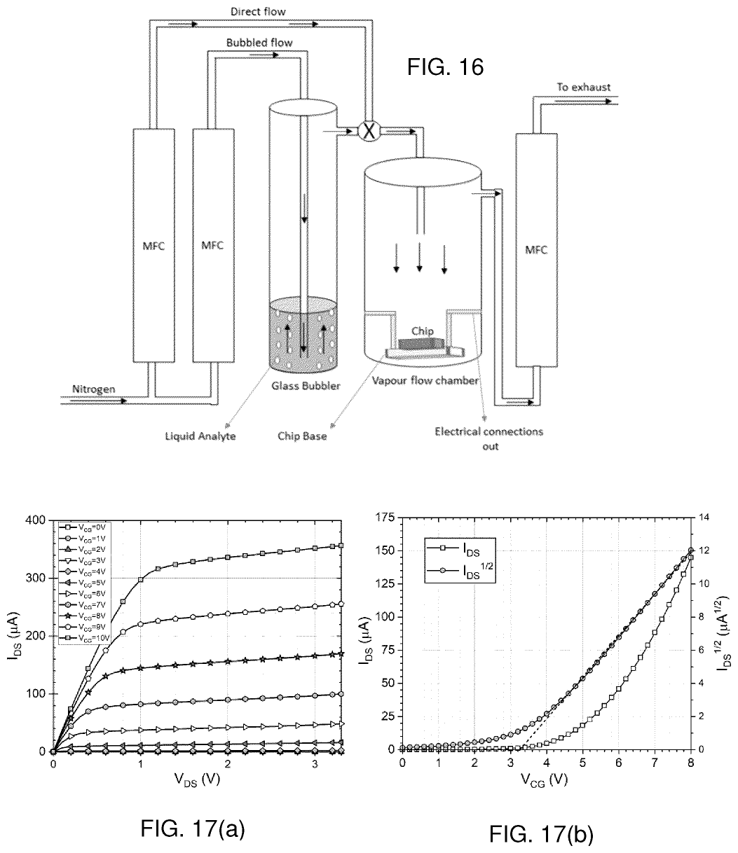

To test electrical properties of polymer-functionalized sensors in an analyte environment, a gas flow apparatus was designed using mass flow controllers. The concentration of analyte vapour in the gas flow was controlled using the ratio of a direct flow of nitrogen in the test chamber to the nitrogen flow through a glass bubbler filled with liquid analyte. A schematic diagram of the gas flow apparatus is shown in FIG. 16. The glass bubbler was filled with the analyte under test and a controlled flow of nitrogen was bubbled through the analyte to carry analyte vapour in the flow chamber. The reaction chamber has a base where the chips were easily mounted and replaced whenever required. The chip base has electrical “pass-through” connectors to the external world, used to enable external connection for the required electrical signals. In these experiments, the concentration of analyte vapour in the flow chamber was kept to a simple percentage, calculated from the ratio of nitrogen flow through the analyte to total nitrogen flow in the chamber. For the initial experiments, the direct flow of nitrogen was turned off and 100 sccm of nitrogen flow was allowed through the analyte filled bubbler unit, this is considered to be 100% analyte vapour flow.

Before the polymer deposition and system characterization, the individual FGMOS sensors were tested for their electrical performance in absence of polymers on their floating gate extension pads. The operation of the FGMOS sensor with any one of its gates used to control the channel in the substrate is expected to resemble a normal MOS transistor. The effective dielectric thickness for control gate is around 5 times that of the gate oxide thickness between floating gate layer and the substrate. The thickness of dielectric layer between gate and substrate has an inverse relationship with the magnitude of field produced in the dielectric. Therefore, it is expected that the control gate terminal requires higher voltages compared to floating gate, for the same equivalent source-drain current in the channel. In FIG. 17 (a) the source-drain current characteristics of the FGMOS sensor is shown. The tested device has a gate width of 10 um and a gate length of 1 um. The experiment shows the response for different control gate voltages in a nitrogen environment. From the drain characteristics is can be observed that the operation of the sensor resembles that of a normal n-MOS transistor.

The magnitude of source-drain current was observed to be less than 10⁻⁶ A for small control gate voltages. To have better insight into the gate control (V_{CG}) over the source-drain current (I_{DS}), the sensor was biased with a constant drain voltage, V_{DS}=1 V for which the control gate voltage (V_{CG}) was swept from 0-8V and the resultant source-drain current was measured. This data is shown in FIG. 17 (b). It can be observed that control gate voltage V_{CG}>3 volts resulted in a source-drain current in the desired range ˜10⁻⁵ A. Analysis of data from this measurement revealed that the threshold voltage with respect to control gate operation was very close to 3V. Therefore, it is expected that the subthreshold regime of these sensors would be in the range of 3 and above.

The floating gate extension pads of the sensors were coated with polypyrrole from a solution of a 0.1 M solution of a pyrrole monomer in a 0.1 M solution of H₂SO₄ at a redox potential of 0.7V. This polymer-coated sensing device was kept in nitrogen environment at a constant source-drain current I_{DS} (>10⁻⁵A) using a constant electrical biasing conditions. An Agilent 34401A digital multimeter and an Agilent 33220a function generator were programmed using LabVIEW to automate the measurement processes.

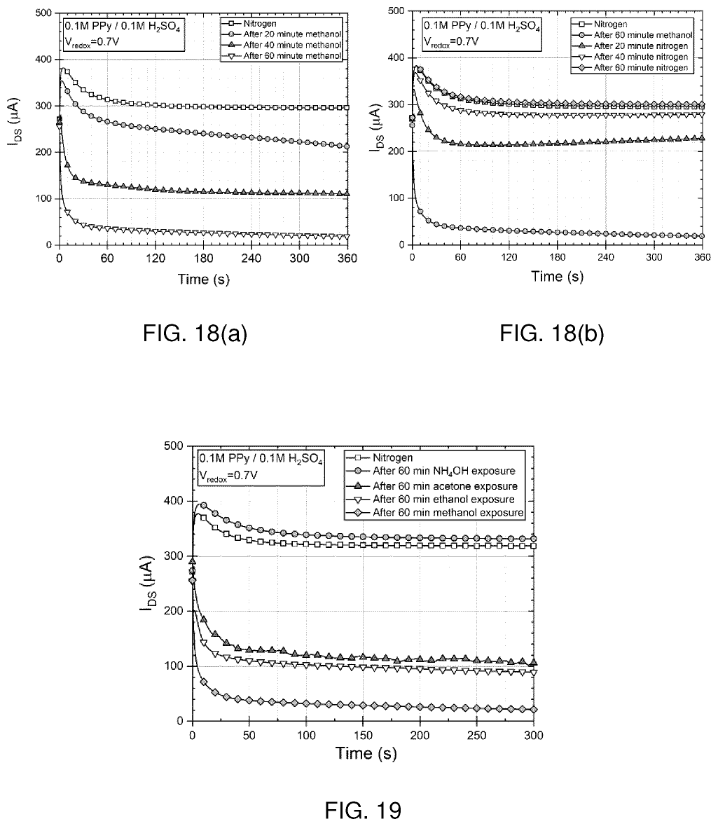

The nitrogen flow conditions were maintained for several hours during which no noticeable change in the sensor source-drain current was observed. The first analyte vapour that was used to test these sensors was methanol. The glass bubbler was filled with 20 ml methanol through which and 100 sccm of nitrogen was bubbled through the liquid while the direct flow of nitrogen was turned off thus generating a 100% methanol environment. The constant electrical bias was applied for a 5-minute interval and the sensor source-drain current was measured many times during this interval. This experiment was repeated three times with measurements taken every 20 minutes. In FIG. 18 (a) the change in the source-drain current is shown after exposing the sensor to a 100% methanol environment. It has been previously observed that the polymers conductivity return to their baseline properties if the nitrogen environment is maintain for a sufficient length of time[24]. The data shown in FIG. 18 (b) confirms these observations in terms of the electrical operation of these sensors, such that the source-drain current returns to its initial magnitude after a prolonged exposure to nitrogen flow.

These results from the methanol vapour experiment confirmed the feasibility of the sensors to detect at least methanol vapour. To ensure the operations with other vapour analytes, similar experiments were conducted using other analytes including, but not limited to, ethanol, acetone and ammonium hydroxide. The polymer coated sensing device was exposed to each of these vapours for an interval of 65 minutes. The sensor source-drain currents were measured for the last 5 minutes of the exposure and compared. A comparative analysis for these measurements is shown in FIG. 19. The source-drain current of these sensor achieved a unique steady state current value for each of the tested vapour analytes.

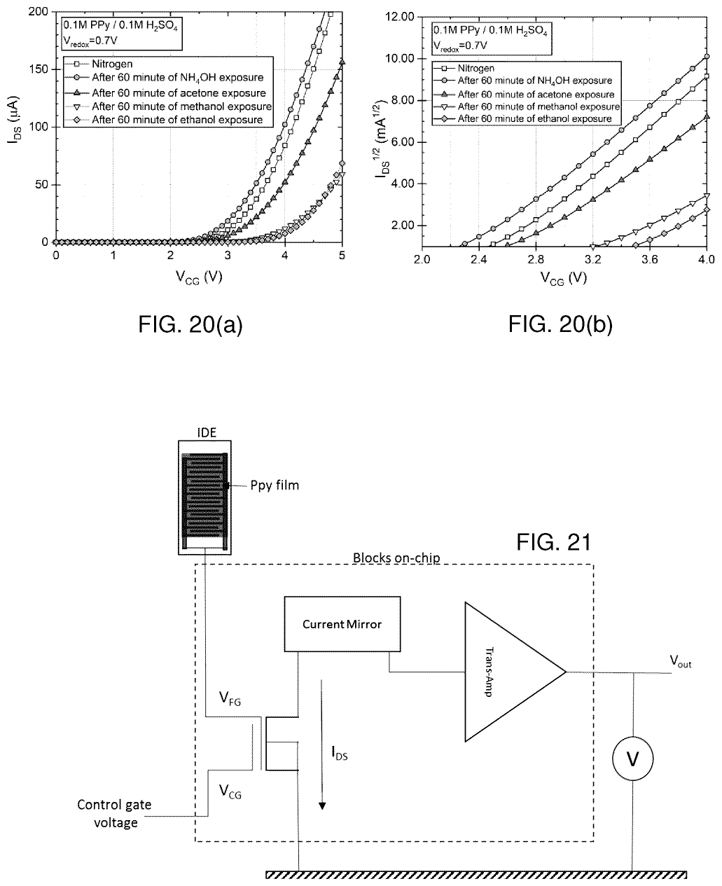

In another experiment, the sensor transfer characteristic was measured by sweeping the control gate voltage from 0-5V while maintaining a constant source-drain potential of 3.3V. This was repeated after exposing the sensor to each of the four different analytes for a period of one hour. In FIG. 20 the shift in the source-drain current is shown after exposure to these analytes. Four distinct source-drain current traces corresponding to each of the analyte exposures can be seen when compared to the initial calibrated nitrogen exposure. Since the source-drain current (I_{DS}) scales with the square of the gate voltage (V_{CG}) in subthreshold regime, the square root of the sensor current (shown in the inset of FIG. 20) shows this effect more dramatically especially between control gate voltages in the range of 2-4 V. The different x-axis intersection points of these traces represent the shift in threshold voltage of each sensor under influence of a particular analyte. These experimental results confirmed that the sensor operation is able to produce distinguishable electrical responses upon exposure to different analytes.

In addition to the aforementioned experiments performed on individual sensors of the array under analyte influence, a next phase of experiments were performed in which the core electrical system on the chip was tested under different analyte environments. One chip was designed in a way that every circuit block could be tested individually. This also produced some flexibility to allow externally coupled separate electrodes pads that were coated with a conducting polymer to the circuitry on the chip. The externally coupling of a polymer coated electrode to the chip's circuitry had the advantage of being an easy test setup, and allowed for the ability to try different polymer options onto a single sensor setup, thus giving the option to reuse one chip without getting it involved in multiple chemical processes, saving time in post processing of the chip. Therefore, in these experiments, instead of depositing the polymer on the surface of floating gate extension pads on the chip, an external interdigitated electrode (IDE) which was coated with the conducting polymer of interest. Initially these devices were characterized via analyte exposure with the sensor, current mirror and the transimpedance amplifier only. The polypyrrole film was coated on an IDE which was then externally coupled to the floating gate terminal on the chip. A schematic for this test system is shown in FIG. 21.

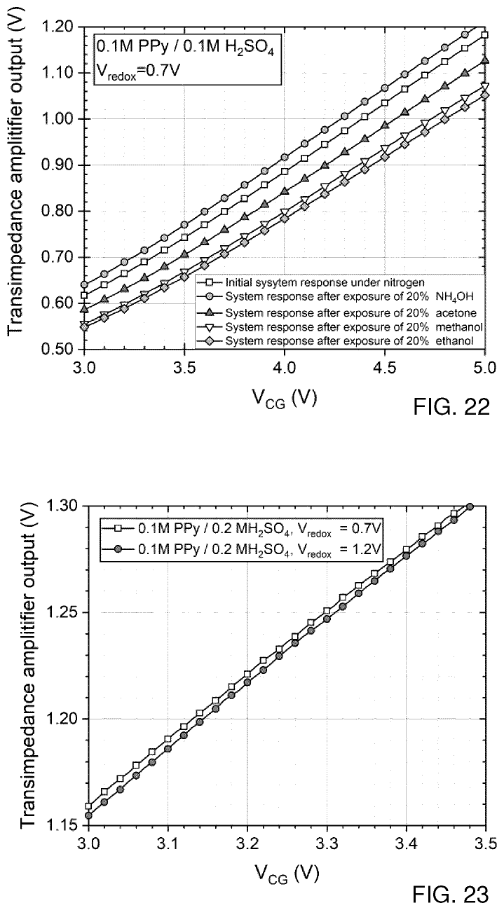

All the aforementioned exposure experiments were repeated for this subsystem and it was observed to function well and produce differentiable voltages at the output of transimpedance amplifier for 100% flow of different analyte vapours. To determine if smaller analyte concentrations could be detected, experiments were conducted in 20% analyte flow by maintaining 120 sccm of direct nitrogen flow and 30 sccm of nitrogen bubbled through the analyte. In the plot in FIG. 22, the transimpedance amplifier output is shown when the sensor was exposed to 20% analyte environment for four different analytes for 1-hour. It was observed that this subsystem of the chip can detect presence of these lower concentrations of analytes, even though the difference in transimpedance amplifier outputs are very small; in the tens of millivolts, demonstrating a need to preferably amplify these signals and scale the measured voltage shift. Having demonstrated the functionality to detect vapour analytes and to produce a measurable electrical response, further tests were performed using different chemical composition of polypyrrole films.

For detection of broad range of analytes, it is preferable to have many chemically diverse polymers with the ability to produce unique responses for many different analytes. Chemical diversity in the conducting polymers, and therefore the uniqueness of analyte response, can be achieved by using different monomer units (Pyrrole, Aniline etc.). This may also be achieved by using different dopants (sulfuric acid, nitric acid or sodium dodecyl sulfate) in the polymeric precursor solution for the electropolymerization process. This may also be achieved by changing the oxidation state of polymer during the electrodeposition, realized by varying the deposition potential[24] applied to the individual floating gate extension pad of different subsets of the sensor array when immersed in the same polymer precursor solution. Several of these methods may be used to develop the required chemical diversity of the conducting polymers. The size of subset selected to share the same extension pad polymer composition may be varied. For example, in one embodiment, each and every sensor in the array may be given a unique polymer composition, in which case only one individual sensor is addressed during a given energization of the float gate signal line in a given immersion of the sensing device in a particular polymer precursor solution. Alternatively, it may be beneficial to have multiple sensors within the array that share the same composition, in which case one or more of the subsets may each features a plurality of sensors that are all addressed during a given energization of the float gate signal line in a given immersion of the sensing device in a particular polymer precursor solution. The electropolymerization step for each different subset can be varied from another in the selected electric deposition potential (e.g. 0.7V vs. 1.2V) applied to the floating gate extension pads of the addressed subset via the floating gate signal line, or in the particular makeup of the polymer precursor solution, whether by variation in the selected monomer units, and/or dopants used therein. The inclusion of multiple sensors within each subset may be advantageous over other embodiments in which each individual sensor has a unique polymer composition from all other sensors, as a shared composition by multiple sensors in the array may be useful, for example, to direct directional movement of an analyte using measurements from spaced apart sensors in the array, or to benefit statistical accuracy.

In a particular experiment, now described, the response of the aforementioned subsystem was measured with two different polypyrrole films electrodeposited at different electropolymerization potentials. A solution of 0.1 M pyrrole monomer solution in a 0.2M H₂SO₄ solution was used to deposit polypyrrole films on two different IDEs at 0.7V and 1.2V. These IDEs were externally coupled to a common sensor setup, one at a time. Each was then exposed to a 30% methanol environment while the output voltage of the transimpedance amplifier was measured after 1-hour of analyte exposure. The measurement results are compared in FIG. 23. It was observed that using these two chemically diverse polypyrrole films, a distinguishable electrical measurement at the output of the transimpedance amplifier was measured. The ability to generate differential measurements for a single vapour analyte is very useful for accurately processing the analyte information in the sensor array. One of the easiest options to introduce chemically diverse films is the changing of the electrodeposition potentials. Other options for generating different chemical derivatives of conducting polymer films may be additionally or alternatively employed.

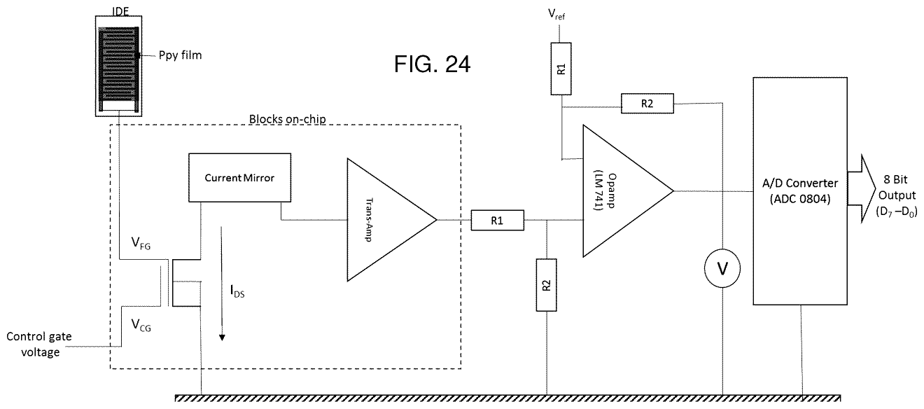

As was observed in the aforementioned experiments, the change in output voltage of the transimpedance amplifier for lower concentrations of any analyte was very small. The minimum resolution of the 8-bit A/D converter is little less than 13 mV. Therefore the resolution of the A/D converter is large with respect to the observed change in output voltage of the transimpedance amplifier. Therefore an on-chip high gain amplifier may be employed to rescale the output voltage of transimpedance amplifier, suitable for the A/D converter operation. To demonstrate the working of the proposed system when such a high gain amplifier is added, the output terminal of transimpedance amplifier was connected to an off-chip high gain differential mode amplifier. The amplifier circuit was designed using LM 741 OPAMP chip. A differential amplification mode was used designed to produce a gain of 10 using suitable values of resistors R1 and R2 (see FIG. 24). The amplified output of this amplifier was fed into an off chip A/D converter (ADC 0804).

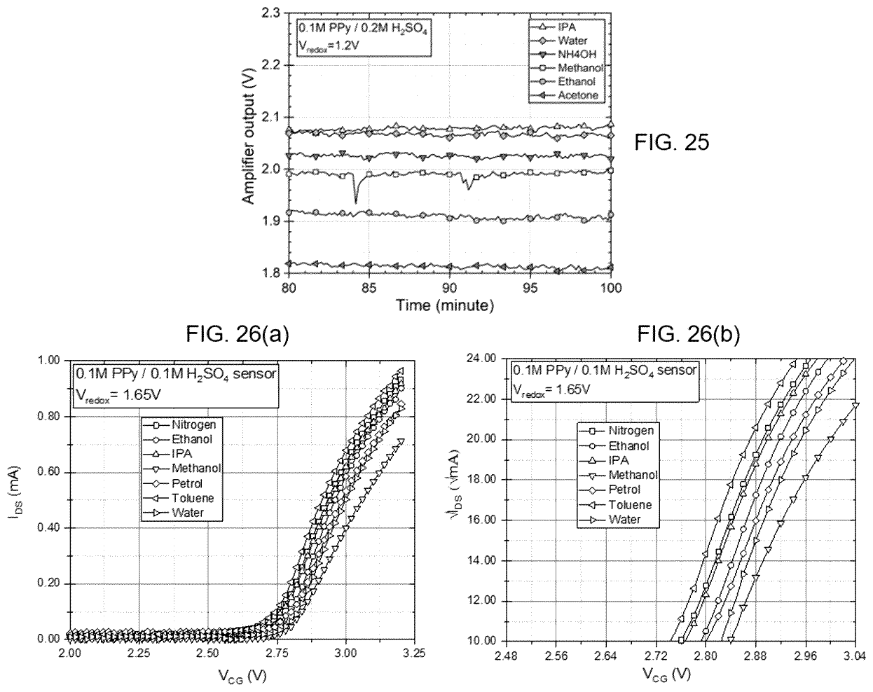

A schematic of this test system is shown in FIG. 24, where the rectangle shown with dashed lines represents circuits from the prototyped sensor chip, while the other circuits were all “off chip” in the test setup, but will be integrated onto the same chip in preferred embodiments of the invention. A polypyrrole coated IDE was again used as external sensing layer. The non-inverting terminal of our differential mode amplifier was used to supply reference voltage (V_{ref}) to tune A/D converter to a desired predefined digital output. The FGMOS sensor was biased for constant source-drain current to trigger a constant digital output equivalent to 112 (decimal) with the nitrogen environment. The system was then exposed to 30% flow of six different vapour analytes individually for 100-minute time intervals. In the plot shown in FIG. 25, the steady state measurements of the amplifier output for all the six analytes are compared. The digital output for all the six measurements compared to reference value under nitrogen is given in Table 1.

TABLE 1
The digital output for system for six different
vapour analytes with respect to nitrogen

| | Flow | Measured | Equivalent |
|---|---|---|---|
| | concentration | digital | Decimal |
| Analyte | to nitrogen | output | number |
| Nitrogen | 100% | 0111 0000 | 112 |
| Isopropyl Alcohol | 30% | 0110 1011 | 107 |
| Water | 30% | 0110 1001 | 105 |
| Ammonium Hydroxide (NH4OH) | 30% | 0110 0111 | 103 |
| Methanol | 30% | 0110 0110 | 102 |
| Ethanol | 30% | 0110 0001 | 97 |
| Acetone | 30% | 0101 1110 | 94 |

The tested off-chip amplifier was very useful in amplifying and rescaling the small voltage shifts from transimpedance amplifier. The 8-bit digital output generated for each analyte is different and unique. The system can be refreshed to its original digital state by flushing the system with nitrogen. This experiment was a demonstration of desired electrical operation of the full proposed system.

From the forgoing disclosure, the manufacturability and operably of the individual sensors and the collective sensor array system have been demonstrated. In design of these olfactory sensors, the floating gate terminal of each transistor is extended to a contact pad surface designed using the topmost metal layer, which is used for deposition of sensing polymer like polypyrrole. The overall chip with the array of sensors serves as a “sensing platform” where multiple sensing polymers would be used with an array of FGMOS sensors to generate a unique electrical response for many tested analytes. This type of sensing platform would be useful in a wide variety of applications such as the automobile, food, cosmetic, packaging, drug, analytical chemistry and biomedical industries. In such industries, these sensors could be used for a broad and diverse range of purposes including quality control of raw and manufactured products, process design, freshness and maturity (ripeness) monitoring, shelf-life investigations, authenticity assessments etc. A process of electroless gold deposition was developed to coat the extended floating gate extension pads of our FGMOS sensors using a three-stage electroless plating technique where zinc, nickel and then gold layers were deposited, and confirmed using energy dispersive x-ray spectroscopy (EDS) and optical microscope imaging.

The gold-coated floating gate extension pads were used for deposition of the desired conducting polymers. The wirebonds from the chip to the ceramic package were encapsulated using SU8 photoresist, though any other suitable encapsulation material may alternatively be used, to avoid electrodeposition of the polymers onto the gold wirebonds. Electrodeposition the polymers was successfully done on individual off-chip sensors, as well as on the sensors in the chip-integrated array. The sensors in the array were selectively coated for two different chemically diverse polypyrrole films using two different redox potentials during deposition. These two different polymer films were also deposited and tested on interdigitated electrodes that were externally connected to some circuitry on the chip.

In summary of the forgoing experimentation, a special gas flow setup was created to that contained a controlled test environment for exposure of the sensors to the vapour analytes. The polymer coated sensor was tested for different analytes including methanol, ethanol, isopropyl alcohol, acetone, ammonium hydroxide and water. The sensors produced unique electrical responses for each analyte and for different concentration in the gas flow. Once the sensor operation was verified, experiments were performed to test the core processing block of the chip in an analyte environment. The polymers employed in the prototypes have been tested and found to also show sensitivity towards different fuels [24]. Since these polymer coated sensors can be designed to be sensitive to many different analytes, these sensor array systems is applicable to many other industries that include food production, agriculture, cosmetic, wine and spirit production, automobiles and even defence. Given that these chips are fabricated using a relatively simple commercial silicon CMOS technology, it would be very economical to fabricate in mass production. The prototype chip has a relatively small array of only 64 (8×8) sensors. However, the number can be easily increased in other embodiments, and for example may depend only on the number of chemically distinct polymers available for a given application. Larger array systems (1000×1000 or more) would be very sensitive to many different analytes such that a combined response from a large array would enable the use of statistical (pattern recognition, signature analysis, principal component etc.) and even learning algorithms to accurately predict very complex analyte information. Such a system may be useful in many different applications.

In further support of the utility of the invention, the forgoing experimentation employing an external interdigitated electrode (IDE) as an external sensing layer were supplemented by subsequent tests of later prototypes in which the extension pads of the chips themselves were coated with different polymers, and tested in the presence of different analytes. These subsequent “on-chip” experiments were performed using the same experimental setup shown in FIG. 16, and based on the same FGMOS characteristics described above in relation to FIG. 17. The on-chip experiments and results thereof are summarized below, with reference to the appended figures.

### Polymer Coated Sensor Transfer Characteristics

The floating gate extension pad of a first on-chip sensor was coated with a polypyrrole (PPy) film from a solution of 0.1M pyrrole monomer and 0.1 M sulfuric acid (H₂SO₄) in 20 ml deionised water (DI) at a redox potential of 1.65 V. This polymer coated sensor was initially tested for transfer characteristics in a nitrogen environment at a constant V_{DS} of 1 V. An Agilent 4156C precision semiconductor parameter analyzer was used for this measurement processes. The nitrogen flow conditions were maintained for several hours and the measurements were repeated. During this time, no noticeable change in the sensor drain current was observed.

To observe the effect of exposure of a given analyte vapor on the sensor operation, the chip was kept in a 7.60% relative flow of the analyte for 1 hour. The vapour concentration, as mentioned previously, was generated using a mixture of 2140 ml/min of nitrogen with 176 ml/min of bubbled nitrogen through the analyte. The measurements were performed under unchanged electrical conditions. This was repeated after exposing the sensor to 6 different analyte vapors each for a period of one hour. The analytes tested were ethanol, methanol, IPA, petrol (gasoline), toluene and water. The measurement data, (I_{DS} vs V_{CG}) is shown in FIG. 26 for all of these analyte exposures.

The measurement plot shows six visibly distinct drain current traces corresponding to the exposure to each of the analyte compared after the initially calibrated nitrogen exposure. The drain current (I_{DS}) scales with the square of the gate voltage (V_{CG}) in subthreshold regime. The square root of the sensor current (shown in the FIG. 26(b)) shows this effect much more dramatically especially for control gate voltages in the range of 2-4 V. The different x-axis intersection points of these traces represent the new threshold voltage of the sensor under influence of a particular analyte. This experiment showed that a measurable shift in sensor characteristics was evident after exposure to these different analytes.

Further experiments and analysis were performed to develop a fuller understanding of the observed threshold voltage shift. This enabled an estimation of the equivalent charge coupled to the floating gate under an analyte influence. Five other monomer/dopant combinations were used for the synthesis of a new set of polymers. The dopants, oxalic acid (C₂H₂O₄), potassium chloride (KCl) and p-toluenesulfonic acid (C₇H₇O₃S) were used in a 0.1M concentration in 20 ml DI water with a 0.1M concentration of pyrrole monomer to synthesise three new polypyrrole films. The other chemical monomer unit used for the polymerization process was aniline. A 0.1M concentration of aniline monomer was used to synthesise two chemically diverse polyaniline films using dopant of 0.1 M concentrated sulfuric acid and p-toluenesulfonic acid (pTSA).

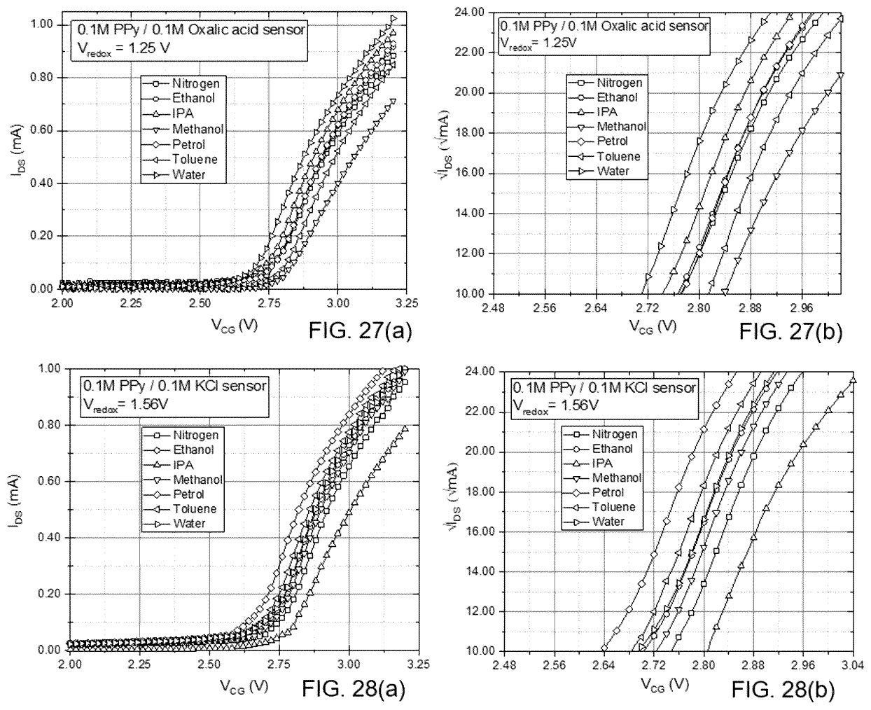

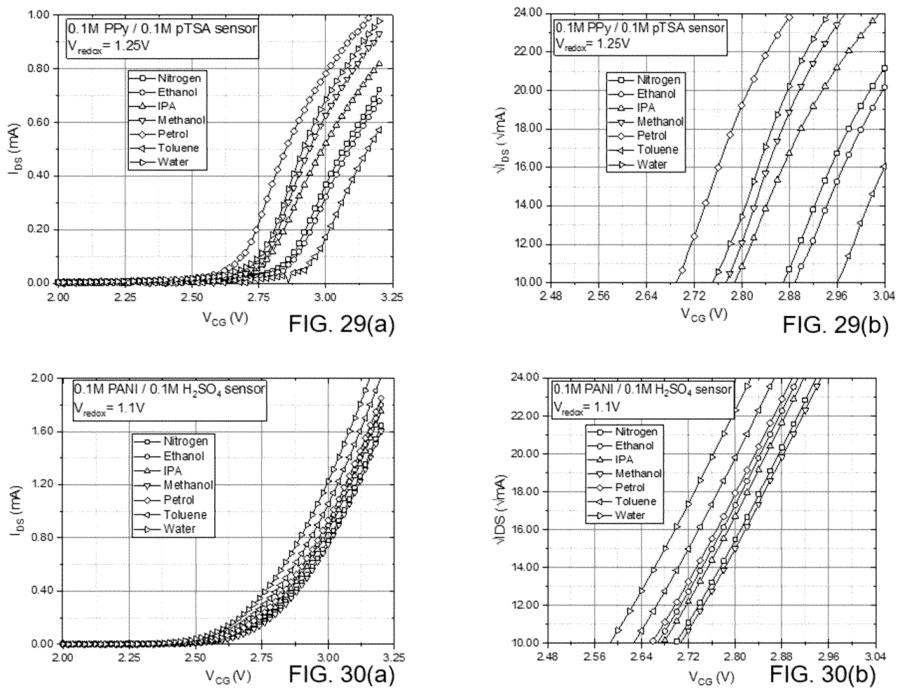

A cyclic voltammetry measurement study of the new polymer recipe indicated a suitable redox potential for growth of each polymer film. For all the polymers discussed herein, the redox potential used to grow the polymer film is mentioned on the measurement data plots. Five new polymer film, integrated sensors were used to repeat the above discussed transfer characteristics experiment. All of the pyrrole-based polymers were integrated with sensors having width to length ratio of 10:1. In FIGS. 27-29, the effect of analyte exposure on these pyrrole-based sensors are shown.

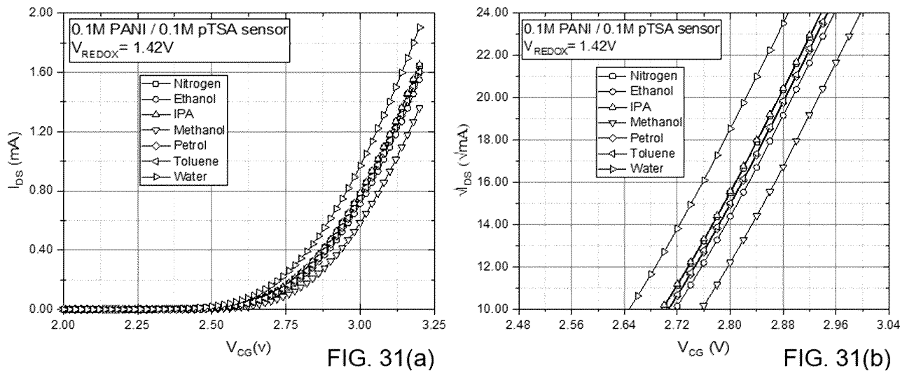

The polyaniline films were integrated to sensors having width to length ratio of 20:1. The width to length ratio of a sensor is directly proportional to the sensor current. Just like the PPy integrated sensors, the polyaniline-based sensors also had sensitivity to the vapour analytes. In FIGS. 30 and 31 these data plots from this experiment are shown. As seen from the experiments shown for all of these devices (FIG. 26-31), each of the sensor/polymer combination has a distinct response to the tested analytes. Exposure to these analytes has shown to cause a very distinct shift in the threshold voltage of the sensors. This observation can be mapped to an effective charge on the floating gate that would cause an equivalent change in the threshold voltage.

To better understand the shift of threshold voltage during analyte exposure, further analysis of the experimental results was performed. The data from FIG. 26(b)-31(b) were used to calculate the threshold voltage using a linear extrapolation method [37]. The control gate had a precision of ±1 mV for all of these experiments. The threshold voltage values, as calculated using this linear extrapolation method are given in Table 2.

TABLE 2
The observed threshold voltage at control gate under influence of vapour analytes

| | Threshold Voltage (V) | | | | | | |
|---|---|---|---|---|---|---|---|
| Polymer | Nitrogen | Ethanol | IPA | Methanol | Petrol | Toluene | Water |
| PPy/H₂SO₄ | 2.76 | 2.79 | 2.765 | 2.84 | 2.8 | 2.74 | 2.82 |
| PPy/Oxalic | 2.77 | 2.765 | 2.74 | 2.84 | 2.77 | 2.81 | 2.71 |
| PPy/pTSA | 2.87 | 2.89 | 2.79 | 2.77 | 2.69 | 2.96 | 2.75 |
| PPy/KCI | 2.75 | 2.70 | 2.81 | 2.72 | 2.63 | 2.68 | 2.69 |
| PANI/H₂SO₄ | 2.70 | 2.67 | 2.68 | 2.71 | 2.66 | 2.63 | 2.59 |
| PANI/pTSA | 2.70 | 2.72 | 2.70 | 2.76 | 2.70 | 2.71 | 2.65 |

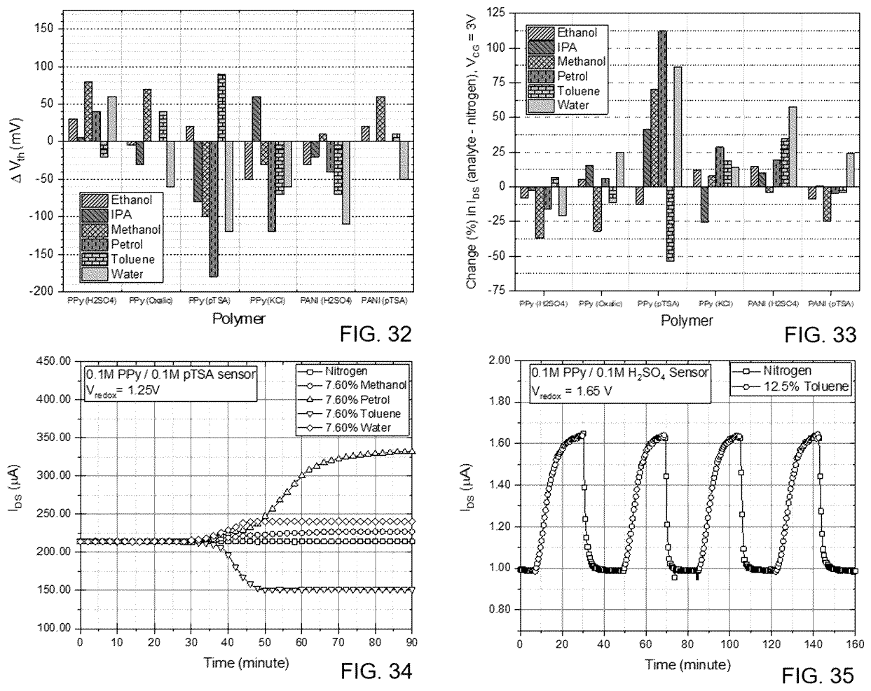

The observed change in threshold voltage (ΔV_{THN}) was calculated as the change in the threshold voltage under the influence of an analyte relative to its magnitude under the nitrogen environment. The observed ΔV_{THN} value for these experiments is given in Table 3. In FIG. 32 a graphical representation of this change is shown in the form of a bar chart. In this figure, it can be observed that the electrical response of the sensor/polymer combination is quite unique for each of the tested analytes. A collective information set from each group of sensor/polymer pairs would then be able to produce unique ‘fingerprint’ for a given tested analyte.

TABLE 3
The Observed change in threshold voltage
(Δ V_{THN}) relative to Nitrogen

| | Observed change in threshold voltage | | | | | |
|---|---|---|---|---|---|---|
| | (ΔVTHN, mV) relative to nitrogen exposure | | | | | |
| Polymer | Ethanol | IPA | Methanol | Petrol | Toluene | Water |
| PPy/H₂SO₄ | 30 | 5 | 80 | 40 | −20 | 60 |
| PPy/Oxalic | −5 | −30 | 70 | 0 | 40 | −60 |
| PPy/pTSA | 20 | −80 | −100 | −180 | 90 | −120 |
| PPy/KCI | −50 | 60 | −30 | −120 | −70 | −60 |
| PANI/H₂SO₄ | −30 | −20 | 10 | −40 | −70 | −110 |
| PANI/pTSA | 20 | 0 | 60 | 0 | 10 | −50 |

The olfactory system is designed to operate in the subthreshold regime. In the subthreshold regime, a small change in the gate bias is able to produce orders of magnitude changes in the sensor current. The performance of this system in the subthreshold regime was analyzed. For the experimental data shown in FIGS. 26-31, it can be observed that the maximum change of drain current for a sensor is not confined to a single voltage point for all of the sensors. Given that a common applied voltage for all the sensors would make comparative analysis more convenient, a voltage of 3 V in the subthreshold regime was selected for analysis of the change in sensor current response upon exposure to the analytes. The sensor drain current (I_{DS}) with a control gate voltage of 3 V for all the sensor/polymer groups was logged into a single table. This data was then processed to calculate the percentage change in the analyte modulated sensor current normalized to a nitrogen in that flow device, under the same conditions. In FIG. 33 a bar diagram, useful for a comparative analysis of the sensor response to the different analytes, is shown. It can be observed that the response of the sensor/polymer combination is quite unique for most of the test analytes. A change of 10% or higher was frequently observed. The results motivated a study of the sensor biased at constant voltages in the subthreshold regime for prolonged exposure to different analytes.

### Sensor Transient Response

A set of experiments were designed in an effort to test the transient performance of the sensors and analyse the final steady state equilibrium response upon exposure to any given analyte. In this set of experiments, the polymer coated sensor was initially kept in nitrogen environment at a constant drain current I_{DS} (>10⁻⁶ A) using a constant electrical biasing condition. The nitrogen flow conditions were maintained for several hours during which no noticeable change in the sensor drain current was observed. After the nitrogen measurements, the sensors were subjected to the analyte exposure at a known flow ratio. The sensor current was measured continuously throughout the nitrogen and analyte exposure cycles.

### Polypyrrole Based Sensors

A pTSA doped PPy based sensor was tested for transient response to four different analytes. The sensor was initially kept in a saturated nitrogen environment by maintaining a constant flow of 2140 ml/min of nitrogen in the vapour chamber. The experiment began with the application of 3 V DC bias to control gate of the sensor and the sensor current was measured. A glass bubbler was prepared for analyte test by filling it with 20 ml of analyte liquid. After 30 minutes, 176 ml/min of nitrogen was bubbled through the glass bubbler while the direct flow of nitrogen was maintained at 2140 ml/min. As stated previously, flow ratio was described as 7.60% of total analyte containing flow. The bubbled nitrogen, acting as a carrier gas, carries analyte particles into the test chamber. The measurements were concluded after 90 minutes. The sequence was repeated for four different analytes; methane, petrol, toluene and water. The measured data of the experiment is plotted in FIG. 34.

It was observed that the sensor current remained constant under the nitrogen flow while a unique response to every exposed analyte was seen. The response time of the sensor was observed to vary for different analytes. The PPy/pTSA film integrated into this sensor showed its highest sensitivity to petrol. However, this sensor also had the slowest response time for a petrol exposure. The sensor had fastest response time for water vapours. The water absorption properties of polypyrrole are already known[38]. Toluene is the only one of the four tested analytes to cause a decrease in the sensor current. The experimental results do confirm that the sensor operation is able to produce distinguishable electrical responses upon exposure to these different analytes.

In a next experiment, shown in FIG. 35, the sensor recovery and repeatability were analysed for a H₂SO₄ doped PPy sensor. In this experiment, a sensor integrated with a polypyrrole film, synthesised from 0.1M pyrrole and 0.1M H₂SO₄ solution at a redox potential of 1.65 V, was exposed to alternate cycles of nitrogen and toluene(12.5%). The sensor was biased very low in the subthreshold regime with a current of ˜1 μA with a control gate potential of 2.74V. The mass flow controller for toluene flow was switched ON and OFF in random intervals between 20-30 minutes. It can be observed that the sensor operation is very repeatable proving that the nitrogen is very effective in returning the sensor back to its original response. The toluene exposure results in a close to a 60% change in the sensor current, relative to the nitrogen exposure characteristics. For the sensor in previous experiment (FIG. 34), the toluene exposure resulted in decrease in the sensor current, whereas for the sensor in this experiment, the observations are contrariwise. The sensors in both of these experiments were integrated with polypyrrole as the conducting polymer. However, the dopants used for synthesis of these films was different, pTSA in the first case and H₂SO₄ for the second The polymer films from different dopants would normally be expected to have different physical and chemical properties [24].

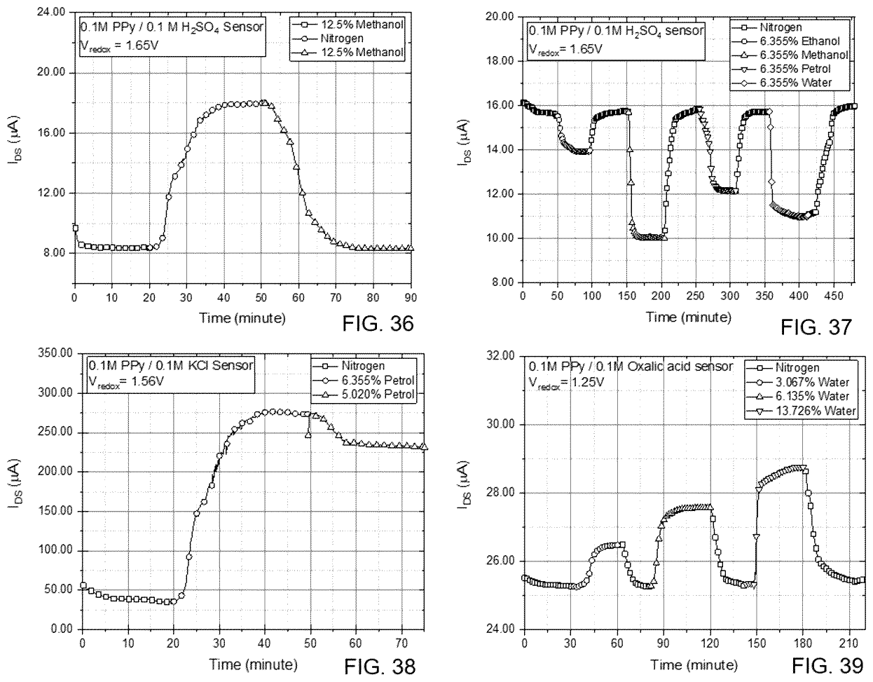

The same sensor was subsequently exposed to methanol vapours and the measurement data is plotted in FIG. 36. For the methanol exposure experiment, the sensor was biased higher up in the subthreshold region; a greater voltage of 2.88 V. Unlike the other experiments, this time the sensor was initially kept under a saturated flow of methanol vapours (12.5%). After 20 minutes, the methanol flow was turned off. A direct flow of nitrogen was introduced and was been seen to increase the current. The sensor current reached a saturated value under nitrogen 20 minutes after the methanol flow was turned off. After 50 minutes total time, the nitrogen bubbled through the methanol was turned back on. The sensor was observed to quickly respond to the methanol flow and it took 15 minutes of response time to return to the initial current value.

The PPy/H₂SO₄ integrated sensor was tested for continuous exposure to 4 different analytes with a nitrogen cycle between each of the different exposures. The analytes were exposed for 50 minutes of time followed by 50 minutes of pure nitrogen prior to exposure to a different analyte. For the nitrogen cycle, the bubbled flow of nitrogen through the analyte is turned off. The analyte from bubbler is removed, the bubbler is cleaned with DI water and dried with compressed dry air. The bubbler is then filled in with 20 ml of next analyte under test and is carefully refitted into the gas flow setup. In FIG. 37 the data from this this experiment is shown. It can be observed that the sensor has a unique sensitivity for all 4 analytes. Of the four analyte vapours the sensor is most sensitive to methanol and is least sensitive to ethanol. This experiment verifies that through the continuous testing of the sensor shows uniquely different responses to each of the analytes.

The next dopant that was used for synthesis of a polypyrrole film was potassium chloride (KCl). The redox potential for synthesis of this conducting polymer film was 1.56V. The PPy/KCl polymer, integrated sensor was tested for sensitivity to different concentrations of petrol. As before, the sensor was initially kept under nitrogen environment for 20 minutes. It was then exposed to 167 ml/min of nitrogen bubbled through petrol. This flow was maintained for next 30 minutes. With reference to FIG. 38, it was observed that the sensor current increased by almost a factor of 8 in less then 20 minutes where it reached a saturated current value. At the 50-minute mark, the direct nitrogen flow through petrol was increased to 2857 ml/min and the bubbled flow of nitrogen through analyte is set to 151 ml/min. In terms of flow ratio, the earlier flow of analyte was 6.35% whereas the present flow is set for 5.02%. The change in concentration of petrol vapours in the vapour chamber had a direct effect on the sensor current. The sensor current began to fall as soon as the petrol concentration was lowered.

Another experiment involved testing for sensor sensitivity to a change in analyte concentration analyte, the results of which are shown in FIG. 39. For this experiment, the conducting polymer film was synthesised at a redox potential of 1.25V from an aqueous mixture of 0.1 M pyrrole monomer with 0.1 M oxalic acid in 20 ml DI water. The sensor integrated with this polymer was tested for water exposure at 3.43 3%, 6.12% and 13.72% flow relative to the nitrogen flow giving a relative change in the current of approximately 5%, 9% and 14%, respectively. Once again, pure nitrogen flow was introduced between each change in the concentration. The sensor was also observed to respond significantly to the increasing concentration of water vapours in the test cavity. The polypyrrole film, which was doped with oxalic acid, showed greater sensitivity to water when compared to the previously demonstrated PPy/pTSA and PPy/H₂SO₄ film-based sensors. In the next section a similar set of experiments are described using the polyaniline conducting polymer-based sensors.

### Polyaniline-Based Sensors

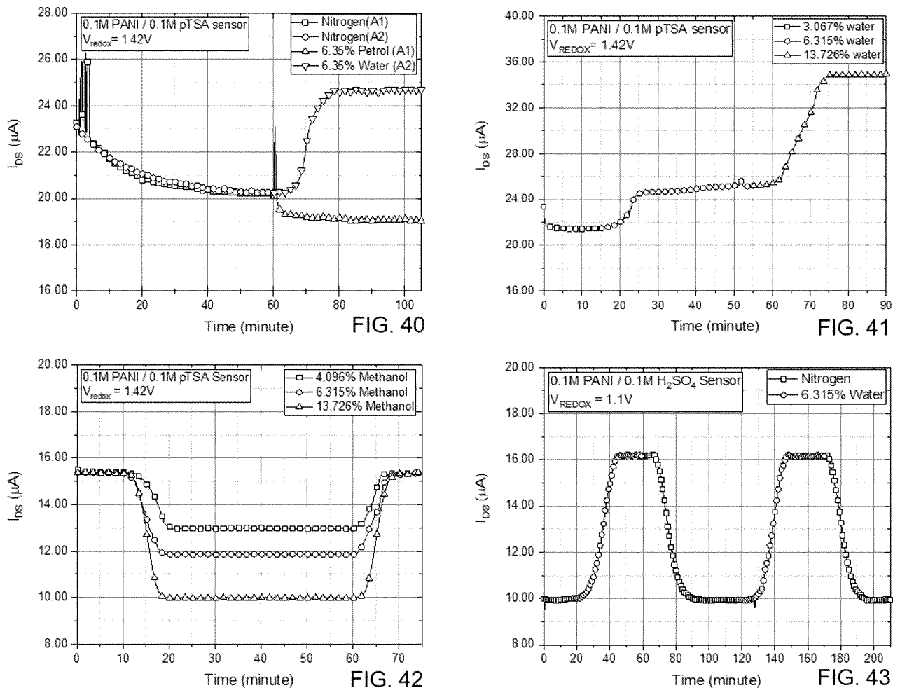

Polyaniline is one of the oldest known conjugated polymer which has been explored for a number of sensing applications [39]. The polyaniline (PANI) film for the following experiment was synthesized using 0.1 M aniline monomer doped with 0.1 M pTSA. The sensor was then tested with exposure to petrol and water. The measurements for both the analytes were performed individually. The data shown in FIG. 40 gives a summary of this experimental data. The sensor was initially kept under nitrogen flow for 60 minutes prior to exposure to the analytes. At the 60 minute mark of the first measurement cycle, the sensor was exposed to water vapours. As a result of this exposure, the sensor current was observed to increase for the next 18 minutes where it finally saturated. This change of sensor current was close to 20%. In the next measurement cycle, the sensor was exposed to petrol vapours after the initial nitrogen exposure. The petrol vapours were found to cause a reduction of the sensor current. This change was less, ˜6%, as compared to the exposure to water ˜22%.

The water vapour exposure test from the previous experiment was performed once again with different concentrations of water vapour. This data for this measurement is shown in FIG. 41. The sensor was kept under a constant flow of 3.05% water vapour for 30 minutes. After this initial time interval, the measurements were started. The sensor remained under this flow of water vapour for 15 minutes. After 15 minutes the water vapour flow was increased to 6.35% water and kept constant for next 40 minutes. This change was observed with a corresponding change in the sensor current of almost 16%. When the water vapour concentration was again increased to 13.72% at 55 minutes, the sensor current responded with a 62% increase. Following this another experiment was performed using methanol vapours. Three different measurements were performed where the sensor was initially kept under nitrogen for 10 minutes and then exposed to different concentration of methanol vapours.

The current response data plot for the PANI/pTSA sensor when exposed to methanol concentration changes is shown in FIG. 42. It can be observed that the sensor current decreases with increasing concentration of methanol. For concentrations of 4.1%, 6.3% and 13.7% methanol the observed saturated values of sensor current were 13 μA, 11.8 μA and 10 μA respectively while the base value for sensor current under nitrogen was 15.5 μA, giving a 16%, 24% and 36% change respectively.

From the sensor transfer characteristics, it was observed that the PANI/H₂SO₄ films have the maximum sensitivity to water vapour when compared to the other test analytes. After gaining an understanding of the sensitivity of the different polymers to changes in analyte concentrations, a PANI/H₂SO₄ polymer-based sensor was tested for repeatability in a series of repeated cycles of nitrogen and water vapour, as shown in FIG. 43. It can be seen that the sensor is very sensitive to water vapour and produces a ˜62% rise in sensor current upon exposure. The refreshing effect of nitrogen can also be observed from this plot.

In summary, the six different polymer based sensors all showed sensitivity for different test analytes. The PPy and PANI films synthesised using different dopants showed unique selectivity of the sensors for all of the tested analytes. The steady state response of the sensors was observed to be very stable under the influence of each vapour analyte.

Since various modifications can be made in this invention as herein above described, and many apparently widely different embodiments of same made, it is intended that all matter contained in the accompanying specification shall be interpreted as illustrative only and not in a limiting sense.

### REFERENCES

[1] L. B. Buck, “A novel multigene family may encode odorant receptors.,” Soc. Gen. Physiol. Ser., vol. 47, pp. 39-51, 1992.
[2] T. Wasilewski, J. G\vec{e}bicki, and W. Kamysz, “Bioelectronic nose: Current status and perspectives,” Biosens. Bioelectron., vol. 87, pp. 480-494, 2017, doi: 10.1016/j.bios.2016.08.080.
[3] M. S. Freund and N. S. Lewis, “A chemically diverse conducting polymer-based ‘electronic nose,’” Proc. Natl. Acad. Sci. U.S.A, vol. 92, no. 7, pp. 2652-2656, 1995, doi: 10.1073/pnas.92.7.2652.
[4] A. A. lyogun, D. A. Buchanan, and M. S. Freund, “Analyte discrimination with chemically diverse sensor array based on electrocopolymerized pyrrole and vinyl derivatives,” RSC Adv., vol. 6, no. 39, pp. 32549-32559, 2016, doi: 10.1039/C6RA03613A.
[5] M. Ramesh Kumar, S. Ryman, M. O. Tareq, D. A. Buchanan, and M. S. Freund, “Chemical diversity in electrochemically deposited conducting polymer-based sensor arrays,” Sensors Actuators, B Chem., vol. 202, pp. 600-608, 2014, doi: 10.1016/j.snb.2014.05.120.
[6] S. E. Zohora and N. Hundewale, “Chemical Sensors Employed In Electronic Noses: A Review,” Soft Comput. Eng., vol. 3, no. 2, pp. 405-408, 2013, doi: 10.1007/978-3-642-31600-5.
[7] J. Gutiérrez and M. C. Horrillo, “Talanta Advances in arti fi cial olfaction: Sensors and applications,” vol. 124, pp. 95-105, 2014, doi: 10.1016/j.talanta.2014.02.016.
[8] R.W. Moncrieff, “An instrument for measuring and classifying odors,” J. Appl. Physiol., vol. 16, no. July 1961, p. Pages 742-749, 1961, [Online]. Available: http://jap.physiology.org.uml.idm.ocic.org/content/jap/16/4/742.full.pdf.
[9] S. W. Chiu and K. T. Tang, Towards a chemiresistive sensor-integrated electronic nose: a review, vol. 13, no. 10. 2013.
[10] P. C. Chen, G. Shen, and C. Zhou, “Chemical sensors and electronic noses based on 1-D metal oxide nanostructures,” IEEE Trans. Nanotechnol, vol. 7, no. 6, pp. 668-682, 2008, doi: 10.1109/TNANO.2008.2006273.
[11] W. Gopel, “From electronic to bioelectronic olfaction, or: From artificial ‘moses’ to real noses,” Sensors Actuators, B Chem., vol. 65, no. 1, pp. 70-72, 2000, doi: 10.1016/S0925-4005(99)00308-1.
[12] S. H. Lee and T. H. Park, “Recent advances in the development of bioelectronic nose,” Biotechnol. Bioprocess Eng., vol. 15, no. 1, pp. 22-29, 2010, doi:

10.1007/s12257-009-3077-1.
[13] H. S. Song, S. H. Lee, E. H. Oh, and T. H. Park, “Expression, solubilization and purification of a human olfactory receptor from Escherichia coli,” Curr. Microbiol., vol. 59, no. 3, pp. 309-314, 2009, doi: 10.1007/s00284-009-9435-6.
[14] K. H. J., “Bioelectronic nose and its application to smell visualization,” J. Biol. Eng., vol. 10, no. 1, p. no pagination, 2016, doi: 10.1186/s13036-016-0041-4.
[15] G. Korotcenkov, Handbook of Gas Sensor Materials, vol. 2. 2014.
[16] K. J. Albert et al., “Cross-Reactive Chemical Sensor Arrays,” 2000, doi: 10.1021/CR980102 W.
[17] T. A. Dickinson, J. White, J. S. Kauer, and D. R. Walt, “A chemical-detecting system based on a cross-reactive optical sensor array,” Nature, vol. 382, no. 6593. pp. 697-700, 1996, doi: 10.1038/382697a0.
[18] W. Jin, H. L. Ho, Y. C. Cao, J. Ju, and L. F. Qi, “Gas detection with micro- and nano-engineered optical fibers,” Opt. Fiber Technol., vol. 19, no. 6 PART B, pp. 741-759, 2013, doi: 10.1016/j.yofte.2013.08.004.
[19] B. Lakard, S. Carquigny, O. Segut, T. Patois, and S. Lakard, “Gas Sensors Based on Electrodeposited Polymers,” Metals (Basel)., vol. 5, no. 3, pp. 1371-1386, 2015, doi: 10.3390/met5031371.
[20] S. J. Park, C. S. Park, and H. Yoon, “Chemo-electrical gas sensors based on conducting polymer hybrids,” Polymers (Basel)., vol. 9, no. 5, 2017, doi: 10.3390/polym9050155.
[21] A. G. MacDiarmid, “‘Synthetic metals’: A novel role for organic polymers (Nobel lecture),” Angew. Chemie—Int. Ed., vol. 40, no. 14, pp. 2581-2590, Jul. 2001, doi: 10.1002/1521-3773(20010716)40:14<2581::AID-ANIE2581>3.0.CO; 2-2.
[22] K. Potje-kamloth, “Chemical Gas Sensors Based on Organic Semiconductor Polypyrrole,” Crit. Rev. Anal. Chem., no. June 2002, pp. 121-140, 2002, doi: 10.1080/10408340290765489.
[23] A. A. lyogun, M. R. Kumar, and M. S. Freund, “Chemically diverse sensor arrays based on electrochemically copolymerized pyrrole and styrene derivatives,” Sensors Actuators, B Chem., vol. 215, pp. 510-517, 2015, doi: 10.1016/j.snb.2015.03.070.
[24] A. A. lyogun, “Chemically Diverse Sensor Arrays Based on Conducting Polymers in Sensing Characterization and Application,” Ph.D. dissertation, Department of Chemistry, University of Manitoba, Winnipeg, 2016.
[25] M. O. Tareq, M. R. Kumar, M. Freund, and D. Buchanan, “An Extended Floating Gate Gas Sensor,” no. 2, pp. 275-279, 2012.
[26] M. O. Tareq, “Floating Gate Metal-Oxide-Semiconductor Based Gas Sensor,” M. Sc. thesis, Department of Electrical and Computer Engineering, University of Manitoba, Winnipeg, 2014.
[27] M. A. R. Barranca et al., “Using a floating-gate MOS transistor as a transducer in a MEMS gas sensing system,” Sensors (Switzerland), vol. 10, no. 11, pp. 10413-10434, 2010, doi: 10.3390/s101110413.
[28] N. Lajnef, N. G. Elvin, and S. Chakrabartty, “A piezo-powered floating-gate sensor array for long-term fatigue monitoring in biomechanical implants,” IEEE Trans. Biomed. Circuits Syst., vol. 2, no. 3, pp. 164-172, 2008, doi:

10.1109/TBCAS.2008.2001473.
[29] S. T. Wang, “On the I-V characteristics of floating-gate MOS transistors,” Electron Devices, IEEE Trans., vol. 26, no. 9, pp. 1292-1294, 1979, doi: 10.1109/T-ED.1979.19595.
[30] A. Thomsen and M. A. Brooke, “A floating-gate MOSFET with tunneling injector fabricated using a standard double-polysilicon CMOS process,” IEEE Electron Device Lett., vol. 12, no. 3, pp. 111-113, 1991, doi: 10.1109/55.75728.
[31] D. Kahng and S. M. Sze, “A Floating Gate and Its Application to Memory Devices,” Bell Syst. Tech. J., vol. 46, no. 6, pp. 1288-1295, 1967, doi: 10.1002/j.1538-7305.1967.tb01738.x.
[32] G. Groeseneken, H. Maes, J. Van Houdt, and J. Witters, “Basics of nonvolatile semiconductor memory devices,” Nonvolatile Semicond. Mem. Technolz., pp. 1-88, 1971.
[33] G. Li and P. Miao, Electrochemical Analysis of Proteins and Cells. Berlin, Heidelberg: Springer Berlin Heidelberg, 2013.
[34] M. Datta, S. A. Merritt, and E. Mario Dagenais, “Electroless remetallization of aluminum bond pads on CMOS driver chip for flip-chip attachment to vertical cavity surface emitting lasers (VCSEL's),” IEEE Trans. Components Packag. Technol., vol. 22, no. 2, pp. 299-306, 1999, doi: 10.1109/6144.774749.
[35] R. G. KING, “Electroplating on Aluminium,” Surf. Treat. Finish. Alum., pp. 34-46, 1988, doi: https://doi.org/10.1016/6978-O-08-031138-8.50010-0.
[36] R. Ansari, “Polypyrrole Conducting Electroactive Polymers: Synthesis and Stability Studies,” CODEN ECJHAO E-Journal Chem., vol. 3, no. 4, pp. 973-4945, 2006, doi: 10.1155/2006/860413.
[37] A. Ortiz-Conde, F. J. Garcia-Sanchez, J. Muci, A. Terän Barrios, J. J. Liou, and C. S. Ho, “Revisiting MOSFET threshold voltage extraction methods,” Microelectron. Reliab., vol. 53, no. 1, pp. 90-104, 2013, doi: 10.1016/j.microre1.2012.09.015.
[38] P. N. Bartlett and S. K. Ling-Chung, “Conducting polymer gas sensors Part III: Results for four different polymers and five different vapours,” Sensors and Actuators, vol. 20, no. 3, pp. 287-292, 1989, doi: 10.1016/0250-6874(89)80127-1
[39] R. E. Martin, T. J. Peckham, and A. B. Holmes, “Conjugated Oligomers and Polymers, Synthesis of,” Encycl. Mater. Sci. Technol., pp. 1509-1526, 2001, doi: 10.1016/b0-08-043152-6/00272-2.

1. A floating gate metal oxide semiconductor (FGMOS) transistor comprising:
a substrate having a source region, a drain region, and a channel region residing therebetween;
gate stack layers deposited on said substrate, among which there is defined a stacked gate structure that resides in overlying relation to the channel region, and comprises, in sequential order starting from said substrate, a first dielectric layer, a floating gate, a second dielectric layer and a control gate;
an extension pad that resides in exposed condition outside said stacked gate structure, comprises a constituent material of an outermost conductive layer of said gate stack layers situated furthest from the substrate, and is conductively linked to the floating gate; and
a floating gate terminal by which an electrical bias is applicable to the floating gate and the extension pad conductively linked thereto for use in electrodeposition of a conducting polymer onto said extension pad.

2. The transistor of claim 1 wherein the extension pad further comprises, in overlying relation to the constituent material of the outermost conductive layer of said gate stack layers, one or more added metal layers that are materially distinct from said constituent material of the outermost conductive layer of said CMOS layers.

3. The transistor of claim 2 wherein the one or more added metal layers comprises an outermost added metal layer of non-oxidizing conductive metal.

4. The transistor of claim 3 wherein the non-oxidizing conductive metal of the outermost added metal layer comprises gold.

5. The transistor claim 3 wherein the one or more added metal layers comprise at least one intermediate added metal layer that resides between the outermost added metal layer and the outermost conductive layer of the gate stack layers, and the at least one intermediate added metal layer is materially distinct from both the outermost added metal layer and the outermost conductive layer of the gate stack layers.

6. The transistor of claim 5 wherein the at least one intermediate layer comprises a zinc layer deposited on the outermost conductive layer of the CMOS layers.

7. The transistor of claim 5 wherein the at least one intermediate layer comprises a nickel layer overlain with the outermost added layer of non-oxidizing conductive metal.

8. The transistor of claim 1 wherein the extension pad further comprises, at an exposed outer surface thereof furthest from the substrate, said conducting polymer applied via electrodeposition.

9. The transistor of claim 1 wherein the extension pad is conductively linked to the floating gate through a stacked bridging structure formed among said gate stack layers, and dielectric layers in said stacked bridging structure have vias through which the extension pad is conductively linked to the floating gate.

10-11. (canceled)

12. A sensing device comprising an array of sensors each comprising a respective transistor of the type recited in claim 1, wherein the extension pads of the transistors of at least some of the sensors comprise outer surfaces composed of polymer material of varying chemical composition to one another.

13. The device of claim 12 further comprising control circuitry that comprises:
decoders from which row and column selection busses run to the sensors for addressable operation thereof; and
for each sensor, a respective pair of buffers whose respective outputs are respectively connected to the floating gate and the control gate of the sensor, whose inputs are respectively connected to floating and control gate signal lines, and whose output enablement terminals are connected to a respective pair of the row and column selection busses.

14. The device of claim 13 wherein the control circuitry further comprises:
a counter;
a plurality of multiplexers each having a first input, a second input and an output, of which the first input is connected to the counter and the output is connected to one of the decoders; and
a set of user-controlled address lines that are respectively connected to the second inputs of the multiplexers;
whereby the sensors are addressable on an automated basis by the counter in a first operational mode passing signals through the multiplexers from the first inputs thereof to the decoders, and addressable on a user-designated basis in a second operational mode passing signals through the multiplexers from the second inputs thereof to the decoders.

15-18. (canceled)

19. The device of claim 12 wherein the array of sensors all reside on a singular chip and share a common substrate.

20. The device of claim 13 wherein the control circuitry and each transistor reside on a singular chip and share a common substrate.

21. (canceled)

22. A method of producing the sensing device of claim 12 comprising performing electrodeposition of chemically diverse polymeric films onto the extension pads of different subsets of said sensors basis by, for each subset of said sensors, applying an electrical bias to the extension pad(s) of said subset while said subset is submerged in a polymer precursor solution in order to deposit a respective polymer film onto the extension pad(s) of said subset.

23. A method of producing the sensing device of claim 13 comprising performing electrodeposition of chemically diverse polymeric films onto the extension pads of different subsets of said sensors by, for each subset of said sensors, transmitting an address of each sensor in said subset over the row and column selection busses and applying voltage to the floating gate signal line while said subset is submerged in a polymer precursor solution, thereby applying a bias voltage to the extension pad(s) of said subset in order to deposit a respective polymer film thereon.

24. (canceled)

25. The method of claim 22 comprising, for at least two subsets of said sensors, using the same polymer precursor solution for said two subsets, but applying said different bias voltages to the extension pads of said two subsets to achieve different oxidation potentials during the electrodeposition, thereby varying the chemical composition deposited onto said extension pads of the subsets despite use of the same polymer precursor solution.

26. The method of claim 22 comprising, for at least some of the subsets, using different polymer precursor solutions to achieve chemically distinct polymeric compositions on the extension pads of said some of the subsets.

27-28. (canceled)

29. The method of claim 22 comprising, before performing the electrodeposition of polymeric film onto one or more of the subsets, depositing one or more added metal layers onto the outermost conductive layer of the gate stack layers at the extension pad(s) of said one or more of the subsets.

30-35. (canceled)

36. The method of claim 22 comprising, before any submersion of the sensing device into any polymer precursor solution, applying a protective encapsulation agent to conductive components of the sensing device other than said sensors, whereby the wire-encapsulation agent prevents electrodeposition of polymeric material onto said conductive components when submerged in the polymer precursor solution.

37. (canceled)
